(19) United States
(12) Patent Application Publication
(10) Pub. No.: US 2025/0142981 A1
(43) Pub. Date: May 1, 2025

(54) BENDABLE PHOTOVOLTAIC DEVICE PACKAGING STRUCTURES AND ENCAPSULANT MATERIAL CONTAINING CURED SILICONE

(71) Applicant: GSKIN TECHNOLOGYG LTD. CO., Spring, TX (US)

(72) Inventors: Peichen YU, Hsinchu City (TW); Hsuehli LIU, Hsinchu City (TW); Aupam MUKHERJEE, West Bengal (IN); Hsinlung WU, Hsinchu City (TW); Lek Yuan BOONG, Hsinchu City (TW); Padmanabh Pundrikaksha PANCHAM, Hsinchu City (TW)

(21) Appl. No.: 18/692,327

(22) PCT Filed: Sep. 17, 2021
(86) PCT No.: PCT/US2021/050765

§ 371 Date: Mar. 15, 2024

(51) Int. Cl. H10F 19/80; B32B 7/12; B32B 15/06; B32B 17/06; B32B 25/08; B32B 25/10; B32B 25/20; B32B 27/32; B32B 27/36; B32B 37/06; B32B 37/10; B32B 37/12; B32B 37/24; C08J 5/12; C08J 7/12

(52) U.S. Cl. CPC H10F 19/804; B32B 7/12; B32B 15/06; B32B 17/063; B32B 25/08; B32B 25/10; B32B 25/20; B32B 27/322; B32B 27/36; B32B 37/06; B32B 37/10; B32B 37/12; C08J 5/124; C08J 7/12; B32B 2037/243; B32B 2250/40; B32B 2255/10; B32B 2255/24; B32B 2255/26; B32B 2262/101; B32B 2305/72; B32B 2307/3065; B32B 2307/414; B32B 2307/54; B32B 2307/546; B32B 2307/5825; B32B 2307/7246; B32B 2307/7376; B32B 2307/748; B32B 2309/02; B32B 2309/04; B32B 2309/105; B32B 2309/12; B32B 2315/08; B32B 2315/085; B32B 2327/18; B32B 2367/00; B32B 2383/00; B32B 2457/12; C08J 2383/04; C08J 2423/08

(57) ABSTRACT

Disclosed is a bendable and flexible photovoltaic device comprising a photovoltaic cell; an adhesive layer, provided on both sides of the photovoltaic cell; and an encapsule layer, provided on the adhesive layer to encapsulate the photovoltaic cell. The encapsulant layer comprises cured silicone.

### CROSS-REFERENCE TO RELATED APPLICATIONS

### Field of the Invention

The present invention is related to silicone having enhanced surface energy; more particularly, a surface treatment method for producing cured silicone having enhanced surface energy and a photovoltaic sandwich device structure containing said cured silicone having enhanced surface energy as encapsulant material; as well as the various combination of front sheet and back sheet for the photovoltaic sandwich device structure containing said silicone encapsulant material. The present invention is also related to a photovoltaic device having structures for creating step height and stress difference on the photovoltaic matrix that can enhance the bendability and flexibility of the photovoltaic device.

### Background of the Invention

The application of conventional solar panel is limited due to its rigidity nature. It is difficult for conventional solar panel to be integrated with or applied to the surface of soft, curved, or bendable objects. Bendable photovoltaic cells may be realized by utilizing bendable photovoltaic cell material such as copper indium gallium selenide (CIGS) solar panel; however, the power generation efficiency of said material may be low relative to other conventional photovoltaic cell materials such as silicon-based photovoltaic cells. Therefore, another method, such as packaging a plurality of photovoltaic cells into an array of bendable panel packaging, is proposed. However, the increase in process complexity and manufacturing cost may be the biggest drawback for said packaging method. As a result, new methods having lower process complexity and manufacturing cost are desired for the applicability of bendable photovoltaic cells.

Photovoltaic devices such as photovoltaic (PV) cells are typically encapsulated by using ethylene-vinyl acetate (EVA) for providing mechanical support, and electrical and environmental isolation. However, under the exposure to ultraviolet light, EVA decomposes to produce acetic acid, which creates surface corrosion on the encapsulant material and the photovoltaic device. The acetic acid also induces yellowing of the encapsulant material, which decrease the transparency of the encapsulant material. EVA also has poor tolerance to low temperature. On the other hand, silicone is ideal for meeting the needs in the photovoltaic (PV) module structure market. Silicone is highly transparent in the UV-visible wavelength region, which makes silicone an ideal encapsulant material candidate for PV cell and other photovoltaic devices. Furthermore, due to low glass transition temperature (−125° C.) and wide modulus turnabilities, silicone can be formulated to have high flexibility and to be mechanically unchanged over a wide range of temperature; silicone also has stress relieving capability which makes silicone as one of the best encapsulation materials in PV industry. In addition, they can also be constructed into hard/resinous coatings that provide effective durable protection and abrasion resistant while maintaining optical clarity. In a PV module, where the temperature can reach as high as 150° C., it's important that the encapsulant experiences no degradation in properties upon exposing to temperature spikes. Silicone is known for high temperature stability and retention of properties upon exposure to high temperatures for extended periods. Silicones are also known as one of the most flame-resistant polymers.

Although silicone exhibits many physical and chemical characteristic advantages over other polymer materials, due to its low surface energy, silicone cannot adhere to other materials easily; furthermore, it is difficult for common adhesive material to be applied to the surface of silicone. The surface energy of silicone may be increased by using a variety of methods, such as plasma surface treatment, surface cleaning, and adding primer . . . etc. However, these aforementioned conventional methods involve substantial number of complex processes resulting the possibilities of bubbles and voids occurrence between the target substrates and silicone, which is one of the vital failure issues of PV encapsulation. Other adhesion methods were also proposed. These adhesion methods may use environment unfriendly materials which causes environmental contamination and health hazard.

Furthermore, as an example, German patent number DE102011086103A1 titled “Silicone rubber on hotmelt adhesive” achieve a peel strength between cured silicone and other material of at least 50 N/5 cm; however, the peel strength is still insufficient for practical applications.

These aforementioned factors contribute highly to the unpopularity of cured silicone relative to other types of common polymer materials such as ethylene vinyl acetate (EVA), polyvinyl butyral (PVB) and thermoplastic polyurethane (TPU) . . . etc. in PV encapsulation.

### SUMMARY OF THE INVENTION

In one aspect of the present invention, a surface treatment method for increasing the surface energy of silicone is provided. The method comprises: applying a mediator to a surface of a surface energy enhancing material and curing the mediator for forming chemical bond between the mediator and the surface of surface energy enhancing material, wherein the mediator comprises silanes; applying a silicone on the mediator and curing the mediator and the silicone, the mediator crosslinking with the surface energy enhancing material to form chemical bond between the mediator and the surface energy enhancing material. Thereby, a cured silicone having enhanced surface energy is produced.

In another aspect of the present invention, a photovoltaic device having cured silicone is disclosed. The photovoltaic device comprises: a photovoltaic cell; an adhesive layer, provided on a side of the photovoltaic cell; and an encapsulant layer in the front sheet and back sheet, provided on the adhesive layer to encapsulate the photovoltaic cell. The encapsulant layer in the front sheet and back sheet comprises cured silicone, the cured silicone is cured prior to being provided on the adhesive layer. The cured silicone is adhered to the adhesive layer via laminating process.

In one embodiment, the encapsulant layer further comprises a mediator and a surface energy enhancing layer for increasing a surface energy of the encapsulant layer; and the mediator comprises silanes.

In another aspect of the present invention, a method of packaging a photovoltaic cell having cured silicone is disclosed. The method comprises: applying an adhesive layer on a side of a photovoltaic cell; and applying an encapsulant layer on the adhesive layer. The encapsulant layer comprises cured silicone, the cured silicone is cured prior to being applied to the adhesive layer; wherein the encapsulant layer is laminated to the adhesive layer to form a packaging of the photovoltaic cell.

In one embodiment, the method further comprises a step of applying a mediator and a surface energy enhancing layer on the encapsulant layer for increasing a surface energy of the encapsulant layer prior to applying the encapsulant layer on the adhesive layer. Furthermore, the mediator comprises silanes and self-crosslinks with silanes, acrylic acid, methyl acrylate, or acrylic acid ethyl ester.

In another aspect of the present invention, a method of manufacturing a bendable photovoltaic device is disclosed. The method comprises: electrically coupling a plurality of photovoltaic cells to form a photovoltaic matrix; depositing an adhesive layer on a side of the photovoltaic matrix; respectively depositing an encapsulant layer on a side of each of the adhesive layers; placing a molding grid on a side of the encapsulant layer, wherein a space arrangement of the molding grid corresponds to a space arrangement of the plurality of photovoltaic cells; and exerting a mechanical pressure on the encapsulant layer via the molding grid such that the adhesive layers and the encapsulant layers are compressed to fill a space arrangement between two of the adjacent photovoltaic cells to form the bendable photovoltaic device. In one embodiment, the encapsulant layers are cured silicone. The adhesive layer may be ethylene vinyl acetate, thermoplastic polyurethanes, polyethylene terephthalates, and polyurethane. Furthermore, a space arrangement is maintained between each of the tiles of the reinforcing layer such that the space arrangement between the tiles of the reinforcing layer corresponds to the space arrangement between two of the adjacent photovoltaic cells.

In another aspect of the present invention, a bendable photovoltaic device is disclosed, the bendable photovoltaic device comprises: a plurality of photovoltaic cells electrically coupled to form a photovoltaic matrix; an adhesive layer, provided on a side of the photovoltaic matrix; an encapsulant layer, provided on the adhesive layer. A bendable connecting portion is formed between two adjacent photovoltaic cells and filled with the adhesive layer and the encapsulant layer.

In one embodiment, the encapsulant layers is cured silicone. The reinforcing layer comprises a plurality of tiles and each tile has approximately the same size as a photovoltaic cell.

Yet in another embodiment of the present invention, a bendable photovoltaic device is disclosed. The device comprising: a plurality of photovoltaic cells electrically coupled to form a photovoltaic matrix; an adhesive layer, provided on a side of the photovoltaic matrix; and an encapsulant layer, provided on the adhesive layer. A bendable connecting portion between two adjacent photovoltaic cells is formed by exerting a mechanical pressure on a side of the encapsulant layer and the adhesive layer via a molding grid.

In one embodiment, the encapsulant layer comprises cured silicone. The reinforcing layer comprises a plurality of tiles and each tile has approximately the same size as a photovoltaic cell.

### BRIEF DESCRIPTION OF THE DRAWINGS

FIG. 1 is a first schematic view of a structure of the photovoltaic device in accordance with the present invention.

FIG. 2 is a second schematic view of a structure of the photovoltaic device in accordance with the present invention.

FIG. 3 is a third schematic view of a structure of the photovoltaic device in accordance with the present invention.

FIG. 4 is a schematic view of the method for packaging a photovoltaic device in accordance with the present invention.

FIG. 5 is another schematic view of the method for packaging a photovoltaic device in accordance with the present invention.

FIG. 6 is another schematic view of the method for packaging a photovoltaic device in accordance with the present invention.

FIG. 7 is another schematic view of the method for packaging a photovoltaic device in accordance with the present invention.

FIG. 8 is another schematic view of the method for packaging a photovoltaic device in accordance with the present invention.

FIG. 9 is a cross-sectional view of the method for packaging a photovoltaic device in accordance with the present invention.

FIG. 10 is another cross-sectional view of the method for packaging a photovoltaic device in accordance with the present invention.

FIG. 11 is another cross-sectional view of the method for packaging a photovoltaic device in accordance with the present invention.

FIG. 12 is a cross-sectional view of a photovoltaic device in accordance with the present invention.

FIG. 13 is a cross-sectional view of a second photovoltaic device in accordance with the present invention.

FIG. 14 is another cross-sectional view of the second photovoltaic device in accordance with the present invention.

FIG. 15 is a cross-sectional view of a third photovoltaic device in accordance with the present invention.

FIG. 16 is a cross-sectional view of a fourth photovoltaic device in accordance with the present invention.

FIG. 17 is a cross-sectional view of a fifth photovoltaic device in accordance with the present invention.

FIG. 18 is a cross-sectional view of a sixth photovoltaic device in accordance with the present invention.

FIG. 19 is schematic view of a rollable photovoltaic device in accordance with an embodiment of the present invention.

### DETAILED DESCRIPTION OF THE PREFERRED EMBODIMENTS

Embodiments of the present invention will now be described, by way of example only, with reference to the accompanying drawings.

As mentioned earlier, silicone is an ideal encapsulant material for photovoltaic device due to its high transparency in the UV-visible spectrums, high dielectric strength, large coefficient of thermal expansion, wide range of refractive index, excellent tolerance to high optical flux, excellent thermal and environmental stability, flame retardant and thermally conductive, resist to oxidative deterioration, and good resistivity to water. However, as mentioned previously, due to the low surface energy of silicone, it is exceedingly difficult to bond silicone with other materials via conventional adhesive layer such as thermoset plastic, TPU, EVA, and PVB (polyvinylbutyral) . . . etc. Although other conventional methods for bonding silicone with other materials have already exited; however, they usually involve complex procedures which are not cost effective. These factors limit the practicality of silicone. As opposed to the traditional approaches, in one embodiment, the present invention provides a new method for surface treatment of the silicone to increase its surface energy, so silicone can be bonded with other material easily with conventional lamination process or common adhesives known in the art. The present invention not only allows silicone to be applied to the field of photovoltaic device packaging, but also permits silicone to be bonded with other materials such as textile, fiber glass . . . etc.

The lamination process described herein refers to common method for combining a multi-layer structure vian adhesive and thermal energy to bind the multiple layer structure of the photovoltaic device together. This process is used by large majority of photovoltaic devices industry, particularly solar panel manufacturers. A typical lamination process of the photovoltaic device involves applying thermal energy to activate the encapsulant layer and/or the adhesive layer, creating vacuum to remove air and avoid bubble formation in the multiple layer structure of the photovoltaic device, and applying pressure to ensure a good surface contact and adhesion between the multiple layer structure. As an example, in a typical lamination process of photovoltaic device which use ethylene-vinyl acetate (EVA) as adhesive layer, and glass and Tedlar polyester Tedlar (TPT) as backsheet of the photovoltaic cell, during the process of lamination, the photovoltaic device is placed in the lamination machine and heated to maximum135° C. for a period of approximately 20 minutes.

Curing systems of silicone may include platinum, peroxide, condensation, and oxime . . . etc. This is normally carried out in a two-stage process at the point of manufacture into the desired shape and dimension.

Traditionally, silicone curing is performed in a clean room environment, but the environment is oxygen environment only.

As mentioned earlier, to become an elastomeric material, raw silicone (uncured state) needs to undergo curing process. This can be achieved by peroxide curing or addition curing. Peroxide curing may be carried out by using organic peroxides. At elevated temperatures, organic peroxides decompose to form highly reactive radicals which chemically crosslink the polymer chains of the cured silicone. As a result, cured silicone may become highly elastic.

However, peroxide curing may generate residues, acidic byproduct, and polychlorinated biphenyls (PCB) in the cured silicone, all of which are undesirable for longevity and performance of the cured silicone. Therefore, generally speaking, post curing treatment is needed to remove these byproducts from the cured silicone.

In addition curing, elements such as platinum catalyst can be added. The following uses platinum catalyst as an example. The SiH groups in the crosslinker react with the vinyl groups of the polymers to form a three-dimensional network. Platinum catalyst silicone typically comprises several components: platinum catalyst, hydride functional crosslinkers, and cure inhibitors. As an example, in some embodiments of the present invention, platinum-catalyzed HCR yields higher physical properties than peroxide-catalyzed HCR (such as higher transparency, better tensile strength and tear strength). Therefore, platinum-catalyzed HCRs may be applied to more diversified applications.

For exemplary purposes, silicone in the present invention may be referred to high consistency rubber (HCR), fluoro silicone (FSR), or room temperature vulcanize (RTV) cured silicone . . . etc. The physical properties of the different types of silicone are listed below:

TABLE 1

| | Tensile | Tear Strength | Elongation |
|---|---|---|---|
| | Strength | units: | range |
| Type of Silicone Rubber | units: MPa | kN/m | (%) |
| HCR-High Consistency | 4-13 | 9-55 | 90-1120 |
| Rubber | | | |
| FSR-Fluorosilicone Rubber | 9-12 | 18-46 | 160-700 |
| LSR-liquid silicone Rubber | 4-12 | 11-52 | 220-900 |
| RTV-Room Temperature | 6 | 9 | 370 |
| Vulcanize Rubber | | | |

Silicone is chemically stable and exhibit a variety of desirable physical characteristics for application in many fields of industry sectors. However, as mentioned earlier, due to its low surface energy, silicone cannot be combined with other materials through common adhesion process such as lamination. Therefore, the application of silicone is limited in practice. In one embodiment of the present invention, a surface treatment is provided to a surface of the silicone for increasing its surface energy, so silicone can easily be adhered to other materials via conventional adhesive and adhesion process.

In accordance with one embodiment of the present invention, the surface treatment of the present invention involves applying a mediator and a surface energy enhancing material to the surface of the silicone. The silicone mentioned here may be a silicone rubber having a functional group comprising: SiH or —CH═CH₂. A mediator is provided between the silicone and the surface energy enhancing material. As an example, in some embodiments of the present invention, the mediator comprises silanes. However, a person having ordinary skill in the art may find other material having chemical properties similar to silanes as mediator. The mediator act as an interfacial layer and reacts with itself and also with the first layer and the second layer through cross linking and interlocking mechanically via inter-diffusion phenomenon and semi-inter-penetrating network (IPN) phenomena. The mediator may be self-crosslinking silanes. As an example, the surface energy enhancing material may comprise polyurethane (PU) having a functional group comprising isocyanate group, or polyalcohol (hydroxyl group). The double bond of C═N in isocyanate group in the surface energy enhancing material crosslinks and interlock mechanically with the mediator via a functional group containing active hydrogen via inter-diffusion phenomenon and semi-inter-penetrating network (IPN) phenomena. However, the surface energy enhancing material is not limited to PU; other types of polymer having similar properties to PU may be utilized in other embodiments. After the application of the mediator to the surface of the silicone, the mediator may be cured via thermal curing or photo-curing. In the proceeding procedure, the surface energy enhancing material may be applied on the mediator. The mediator respectively bonds with the surface energy enhancing material and the silicone. As a result, chemical bonds are formed between the mediator and the surface energy enhancing material, as well as between the mediator and the silicone. More specifically, the double bond of C═N in the isocyanate functional group in the surface energy enhancing material is highly active and can undergo autopolymerization to form a dimer or a trimer. In some embodiments, the double bond can also undergo addition reaction with functional group containing active hydrogen such as water, alcohol, phenol, acid, or amine. The surface energy enhancing material contains isocyanate group; the mediator can thus crosslink with the surface energy enhancing material via the aforementioned functional group.

In other embodiments of the present invention, in addition to PU, the surface energy enhancing material may also be polymer such as PET, polyimide (PI) . . . etc.

One of the mechanisms for cross-linking the mediator with the silicone is as follows: an addition reaction is carried between the SiH functional group and the double bond; the reaction condition and speed is controlled by the usage of platinum catalyst; therefore, silicone can cross-link with the mediator via SiH functional group or double bond functional group. The mediator and silicone are then cured in the curing apparatus. The curing apparatus is a thermal curing apparatus or a photo-curing apparatus. When the thermal curing apparatus is used, thermal curing apparatus is provided with a predetermined temperature, the thermal curing apparatus is heated with predetermined temperature of 80° C. to 200° C. Thereby, cured silicone having enhanced surface energy is produced.

In another embodiment, for exemplary purpose, the present invention utilizes siloxane functional group condensation polymerization to achieve self-crosslinking reaction of the mediator. The mediator may comprise approximately 1% of trimethoxy(vinyl) silane (CAS: 2768-02-7) and approximately 25% of (3-Glycidyloxypropyl) triMethoxysilane (CAS: 2530-83-8), which are prepared by respectively dissolving them in an organic solution.

In this embodiment, the mediator original solution is diluted with appropriate ratio and combine with the surface energy enhancing material. The mediator and the surface energy enhancing material is cured under 90° C.-150° C. for 3-10 minutes to complete the cross linking and inter locking reaction of the mediator and the surface energy enhancing material before applying to the silicone. In some embodiments, the mediator and the surface energy enhancing material are cured under approximately 130° C. for 3-10 minutes to complete bonding of the mediator and the surface energy enhancing material prior to being applied to the silicone. After applying the mediator and the surface energy enhancing material to the surface of the silicone, the silicone is cured in the curing apparatus with preheated temperature of approximately 110° C. for 3-5 minutes to complete the cross linking and inter locking reaction of the mediator and the silicone. Thereby, a cured silicone having enhanced surface energy is produced. In this embodiment, the chemical bonding force between the surface energy enhancing material and the cured silicone is 55 N/5 cm to 65 N/5 cm.

In another embodiment, for exemplary purpose, the present invention utilizes siloxane functional group condensation polymerization to achieve self-crosslinking reaction of the mediator. The mediator may comprise 3-10% of trimethoxy(vinyl) silane (CAS: 2768-02-7) and (3-Glycidyloxypropyl) triMethoxysilane (CAS: 2530-83-8), which are prepared by respectively dissolving them in an organic solution. The mediator is applied to the surface energy enhancing material. The mediator and the surface energy enhancing material are cured under approximately 130° C. for 3-10 minutes to complete the cross linking and inter locking reaction of the mediator and the surface energy enhancing material. The mediator and the surface energy enhancing material are applied to the silicone; the silicone and the mediator and surface energy enhancing material are cured under approximately 110° C. for 3-5 minutes to complete the cross linking and inter locking reaction of the mediator and the silicone. The chemical bonding force between the surface energy enhancing material and the cured silicone is 90 N/5 cm to 110 N/5 cm in this embodiment. Thereby, a cured silicone having enhanced surface energy is produced.

Based upon the above process, the surface energy of the cured silicone can be improved to approximately 36-38 mN/m (from 20-24 mN/m originally). Thereby, cured silicone can easily adhere to other materials using conventional adhesives or adhesion process such as lamination.

In some embodiments of the present invention, the mediator and surface energy enhancing material may be applied to the surface of the silicone in the form of thin films coating. In this case, the mediator coating is provided between the silicone and the surface energy enhancing material film. After completing bonding between the mediator coating and the surface energy enhancing material film in the curing apparatus, a side of the mediator coating can be bonded with the silicone. In this embodiment, the mediator coating acts as a bonding agent between the silicone and the surface energy enhancing material films. As mentioned earlier, the bonding between the mediator and silicone and the bonding between the mediator and the surface energy enhancing material are realized via the formation of chemical bonding. In this embodiment, the thickness of the surface energy enhancing material films may be from 1-2 μm, and the thickness of the mediator is about 1-5 μm. However, the thickness for the mediator and the surface energy enhancing material films are not limited to these ranges. Since the thickness of the mediator and surface energy enhancing material films are extremely small relative to the thickness of the silicone (typically 100 μm-200 μm), the chemical and physical properties of the silicone would not be interfered by the mediator coating and surface energy enhancing material film. The preparation methods of the mediator and the surface energy enhancing material are the same as the embodiments described above. The chemical bonding force between the surface energy enhancing material and the silicone is 50 N/5 cm to 300 N/5 cm in this embodiment.

In some embodiments, the thickness of the mediator and surface energy enhancing material films may be more than 100 μm. Particularly, the thickness of the surface energy enhancing material can be selected according to different applications.

The cured silicone with enhanced surface energy in accordance with the present invention can adhere to a variety of substrate layer of different materials. For instances, the cured silicone may be applied and bonded with substrate layer such as textile, glass fiber, other polymers, or metal surface . . . etc. In some cases, the substrate layer may be flexible layer selected from polyethylene terephthalate (PET), PC (Polycarbonate), ETFE (Ethylene-tetra-fluoro-ethylene), or Acrylonitrile butadiene styrene (ABS). The cured silicone may be applied and bonded with the aforementioned substrate layers vian adhesives such as: polyurethane reactive (PUR), hotmelt adhesive (HMA), polycarbonate adhesive (PC), acrylonitrile butadiene styrene adhesive (ABS) . . . etc. In some other embodiments, the cured silicone may be applied and bonded with other materials via roll-to-roll process.

In one embodiment of the present invention, both sides of the silicone can be treated with the surface energy enhancing process mentioned above. More particularly, mediator coating is provided to two layers of the surface energy enhancing material films respectively; after curing the two surfaces energy enhancing material films and the mediator, the two surfaces energy enhancing material films are respectively applied to both sides of the silicone for final curing to create cured silicone with both sides treated with surface energy enhancing process.

As an example, in one embodiment of the present invention, the cured silicone may be applied and bonded with textile, glass fiber, or other polymers via polyurethane reactive (PUR) lamination process or other adhesives or mediators. Cured silicone having both sides treated with surface energy enhancing process can be bonded with other material on both sides. The following describes an embodiment in which the cured silicone with enhanced surface energy in accordance with the present invention is used as an encapsulant material of photovoltaic devices.

In one aspect of the present invention, the cured silicone in accordance with the present invention can be adhered to photovoltaic devices via conventional adhesive such as ethylene-vinyl acetate (EVA), ethylene propylene diene monomer (EPDM), polytetrafluoroethylene, polyvinyl butyral (PVB), thermoplastic polyolefin (TPO), and thermoplastic polyurethane (TPU) . . . etc. Furthermore, the cured silicone in accordance with the present invention may be adhered to other layers of the photovoltaic device via lamination process, which is not possible in the prior Unlike the conventional silicone bonding methods, the adhesion process of the cured silicone in accordance with the present invention with the photovoltaic devices can be carried out without high energy consumption and high contamination. Furthermore, the adhesive layer required for bonding the cured silicone in accordance with the present invention with the photovoltaic cell may have a thickness of approximately 0.05 mm to 0.5 mm, which is relatively small when comparing to other encapsulant materials. As a result, the over overall packaging size of photovoltaic device implemented with the cured silicone can be reduced.

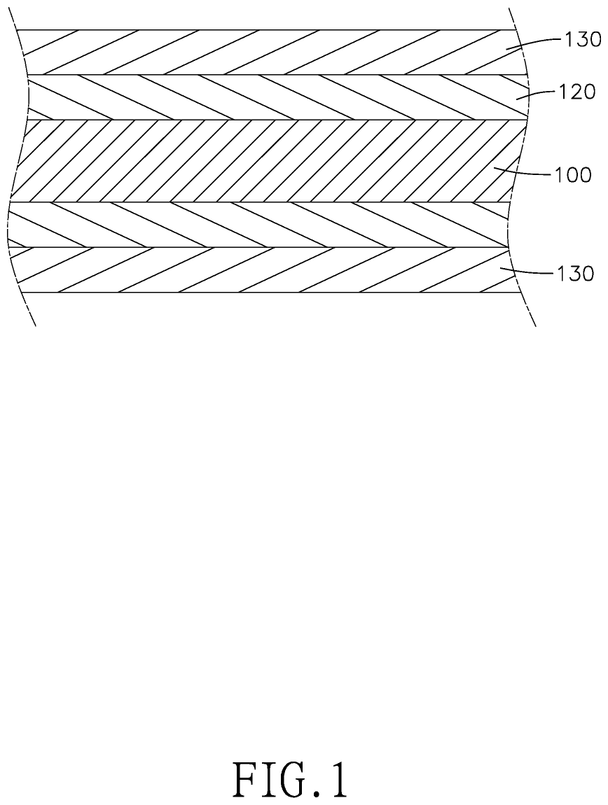

With reference to FIG. 1, in one embodiment of the present invention, the photovoltaic device in accordance with the present invention comprises: a photovoltaic cell 100; an adhesive layer 120 provided on a side or both sides of the photovoltaic cell 100; and an encapsulant layer 130 provided on the adhesive layer 120 to encapsulant the photovoltaic cell 100. At least one of the encapsulant layer 130 comprises cured silicone. The adhesive layer 120 provides peel strength between the cured silicone (which is the encapsulant layer 130) and the photovoltaic cell 100. As mentioned earlier, cured silicone cannot be bonded with other non-silicone-based material easily due to its low surface energy. The surface treatment mentioned earlier is performed on at least one surface of the cured silicone to facilitate the bonding between the silicone and the photovoltaic cell 100.

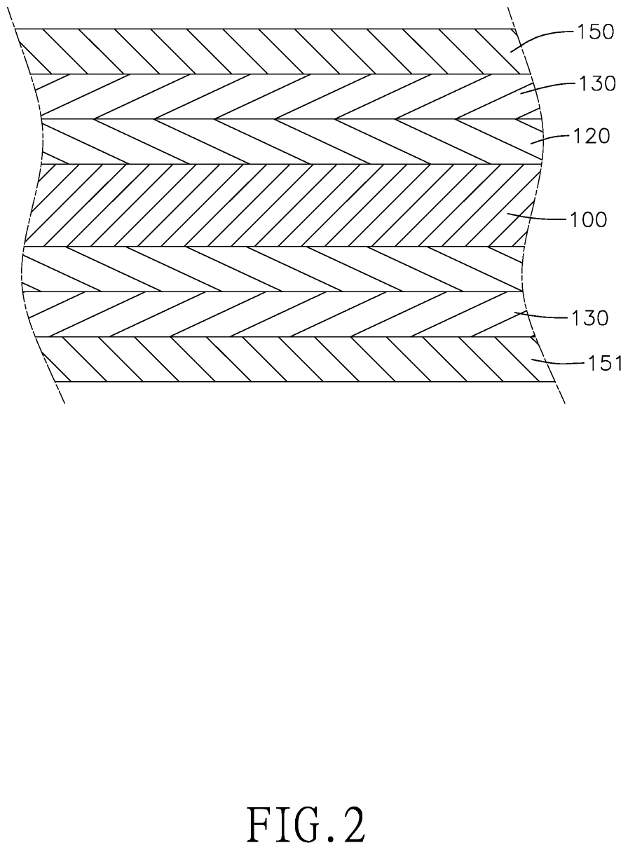

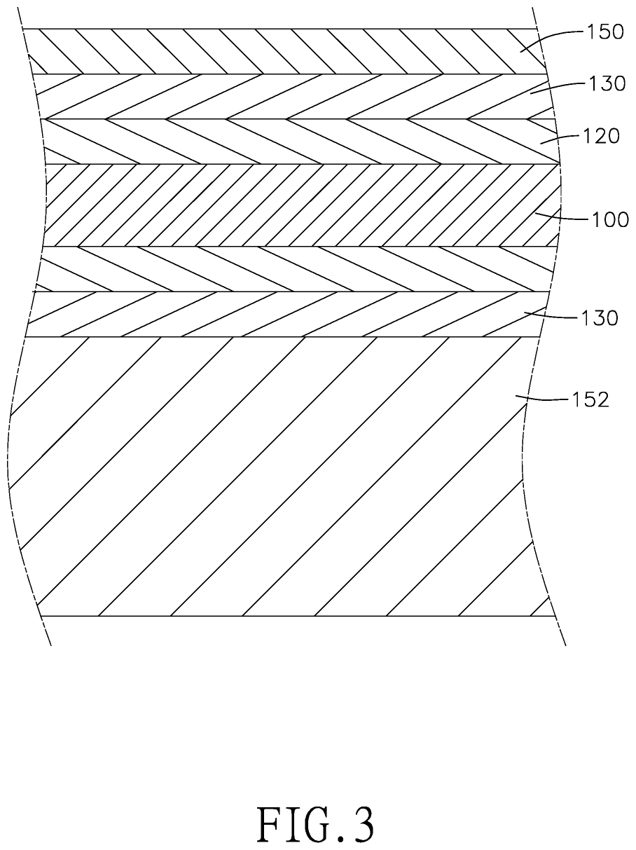

With reference to FIG. 2 and FIG. 3, in some embodiments of the present invention, both sides of the silicone can be treated with the surface energy enhancing material. In this case, a side of the cured silicone, as the encapsulant layer, can be provided with other functional layer 150 to enhance the optical property of the photovoltaic device; while the other side of the cured silicone is adhered to the adhesive layer. The functional layer 150 may be intended to protect the photovoltaic device from UV radiations, and moisture penetration from the environment. It further promotes electrical insulation and durability to the photovoltaic device. In one embodiment, the back sheet 151 and/or the functional layer 150 of the photovoltaic device may be polymer or a combination of polymers, such as fiber glass, polyamide (PA), polyethylene terephthalate (PET), PC (Polycarbonate), ETFE (Ethylene-tetra-fluoro-ethylene), silicone, polyolefin, TPT (Tedlar-Polyester-Tedlar), and polyvinylidene fluoride (PVDF) . . . etc. The back sheet and/or the front sheet may be applied on top of the encapsulant layer to provide additional rigidity to the photovoltaic device. In other embodiment, the functional layer 150 can be anti-reflection coating or water vapor protection layer and substantially transparent.

In the case which fiber glass is used as back sheet to increase high temperature resistance and dimensionally stability of the photovoltaic device, polytetrafluoroethylene (Teflon™) coated glass fiber may be used as the encapsulant layer comprising cured silicone. The use of the combination of polytetrafluoroethylene and glass fiber as back sheet brings the following advantages to the photovoltaic device: stain resistance, lightweight, operating temperature range −50° C. to +260° C., excellent chemical resistance, high electrical insulative and dielectric properties, dimensional stabilities under heat and pressure, low electrical losses, mildew and fungus resistance, and ultra-Violet, infra-Red, Micro-wave, radio frequency resistance. However, cured silicone in accordance with the present invention also has the above advantages as the fiber glass with polytetrafluoroethylene. In addition, cured silicone in accordance with the present invention may be more flexible and tear resistance relative to fiber glass with polytetrafluoroethylene. In some embodiment of the present invention, the combination of cured silicone, polytetrafluoroethylene, and fiber glass can form the encapsulant layer and back sheet of the photovoltaic device.

With reference to FIG. 2, the functional layers 150 may be, but not limited to, water vapor protection layer, anti-reflection coating, polyethylene terephthalate (PET), ETFE (Ethylene-tetra-fluoro-ethylene), silicone and functional layer 151 may be but not limited to reinforcement layer (e.g., fiber glass, polyimide (PI), polyethylene terephthalate (PET), PC (Polycarbonate), ETFE (Ethylene-tetra-fluoro-ethylene), silicone, polyolefin, TPT (Tedlar-Polyester-Tedlar), and polyvinylidene fluoride (PVDF) . . . etc.), water vapor protection layer . . . etc. As mentioned earlier, the functional layers 150 and 151 act as the front sheet and back sheet respectively in the conventional photovoltaic device.

Yet in another embodiment, with reference to FIG. 3, cured silicone having both sides treated with surface energy enhancing material can be adhered to the adhesive layer of the photovoltaic devices, while the other side of the cured silicone is adhered to other object 152 having textile, glass fiber, other polymers, or metal surfaces. As a result, the photovoltaic device having cured silicone as encapsulant layer can be applied to different settings and environments.

The following further describes several detailed embodiments of the structure of the photovoltaic device. The photovoltaic cell mentioned herein may include, but not limit to, photovoltaic cell, and light emitting diode . . . etc. In some embodiments, it may be desirable to assemble a plurality of photovoltaic cells together by electrically coupling the plurality of photovoltaic cells to form a photovoltaic matrix. As an example of the photovoltaic cells, photovoltaic cells are used in the following description. However, the present invention can be easily modified and applied to other photovoltaic cells by a person having ordinary skill in the art.

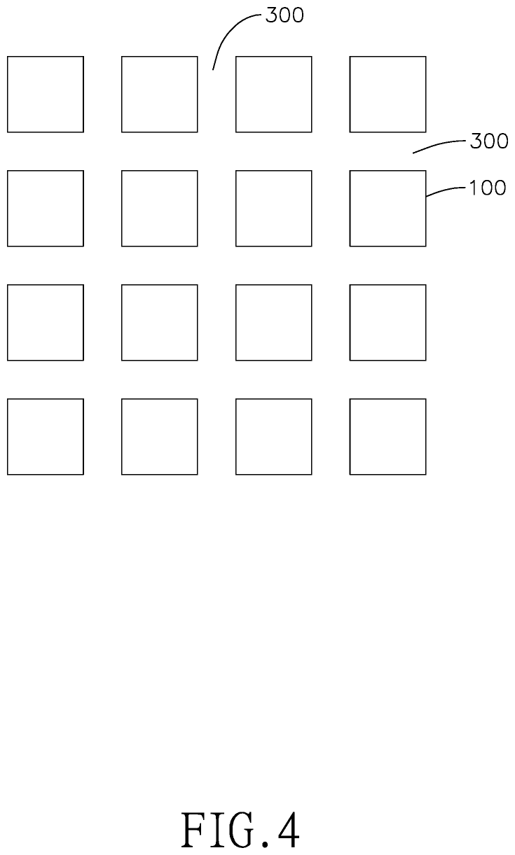

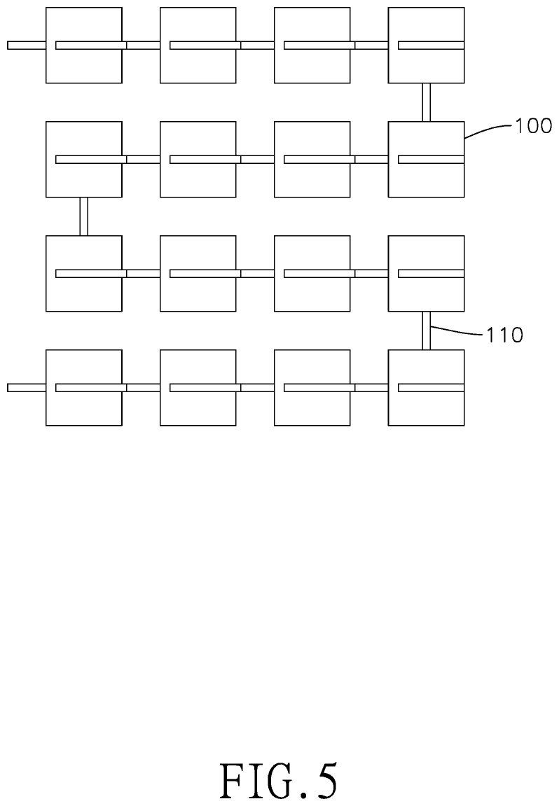

In one embodiment, a plurality of photovoltaic cells is connected in series or in parallel to form photovoltaic matrix according to different types of application. The photovoltaic matrix is then packaged to from a photovoltaic device. The photovoltaic matrix may be rigid or bendable, depending on the packaging material and process of the photovoltaic device. With reference to FIGS. 4, 5, 6, 9 and 10, the method of manufacturing the photovoltaic device comprises the following steps:

Step 001: electrically coupling the plurality of photovoltaic cells 100 to form the photovoltaic matrix. The plurality of photovoltaic cells 100 is connected in series or in parallel; however, other types of electrical connection configurations may also be possible depending on the type of application. Each of the photovoltaic cells 100 is placed next to the other with a space arrangement 300 provided therebetween.

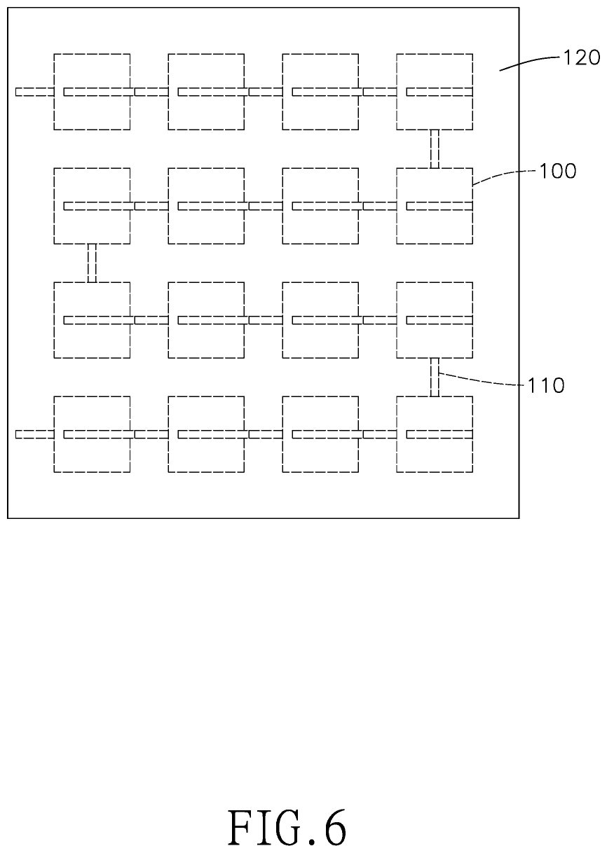

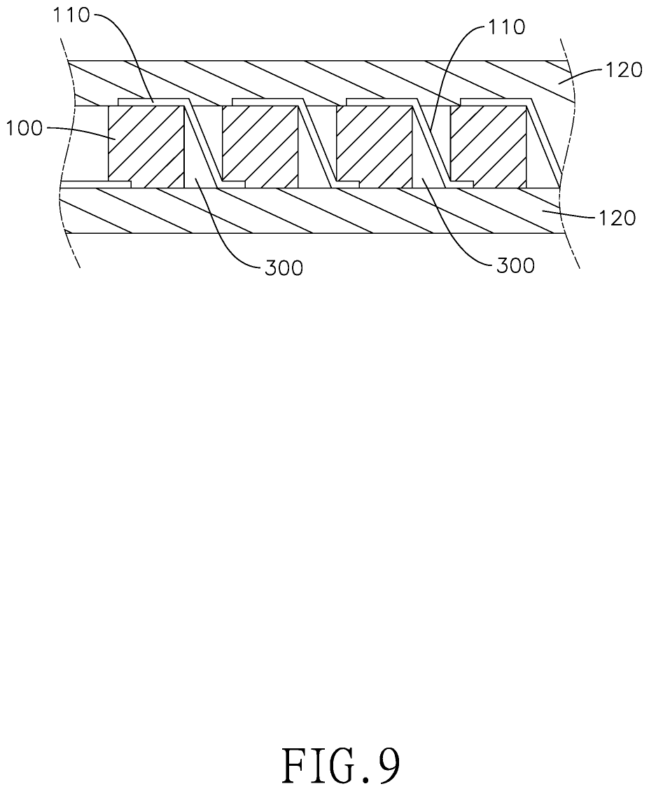

Step 002: depositing an adhesive layer 120 on a side or both sides of the photovoltaic matrix (FIGS. 6 and 9). The adhesive layers 120 may be selected from (but not limited) ethylene-vinyl acetate (EVA), ethylene propylene diene monomer (EPDM), polytetrafluoroethylene, polyvinyl butyral (PVB), thermoplastic polyolefin (TPO), polydimethylsiloxane (PDMS), and thermoplastic polyurethane (TPU). In some embodiments, the adhesive layers 120 are placed directly on both sides of the photovoltaic matrix. As a result, as shown in FIG. 9, a total of two adhesive layers 120 are provided on the photovoltaic cells 100. However, in other embodiments, the adhesive layers 120 may be placed indirectly on a side or both sides of the photovoltaic matrix. More specifically, other layers may come between the photovoltaic cells 100 and the adhesive layers 120.

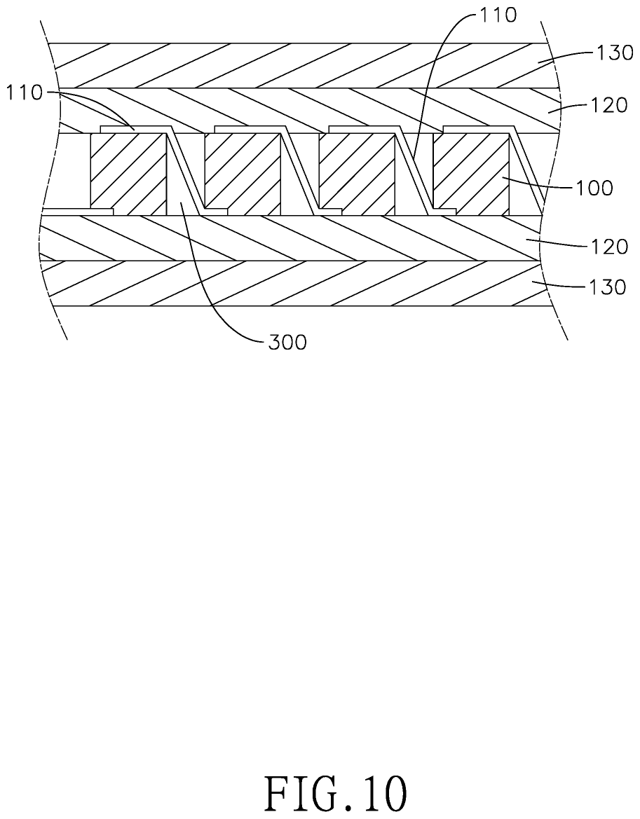

Step 003: respectively depositing an encapsulant layer 130 on a side of each of the adhesive layers 120 (FIG. 10). The encapsulant layers 130 are purposely placed on the most outer layer of the photovoltaic device to resist moisture and external force for preventing erosion and damage of the photovoltaic device. Ideally, the encapsulant layers 130 prefers to be soft, bendable, having good shock absorbent property, good thermal expansion property, and excellent light permeability. In an embodiment of the present invention, at least one of the encapsulant layers 130 is cured silicone having at least one surface treated with the surface energy enhancement method mentioned above.

Step 004: exerting a mechanical pressure on the encapsulant layers 130 such that the adhesive layers 120 and the encapsulant layers 130 are compressed and adhere to each other to form the photovoltaic device. This process is also known as the lamination. As an example, the lamination is carried under approximately 140° C., 100 kPa, for 20 minutes. Thermal energy and mechanical pressure are applied to the adhesive layers 120 for better fluidity and adhesion during the manufacturing process. In some other embodiments, the lamination process involves laminating the adhesive layer and the cured silicone under 90 kPa to 110 kPa of pressure, with process temperature of approximately 100° C. to 150° C. for 15-20 minutes. The heat and pressure generated during the laminating process increase the fluidity and of the adhesive layer, causing the adhesive layer and the encapsulant layer to firmly bond with each other. In another embodiment, the lamination of the adhesive layer and the encapsulant layer is performed under 100 kPa of pressure, with process temperature of approximately 140° C., going through 4 minutes pumping and baking the module for removing the air between the encapsulant layer and the adhesive layer, and moving forward to 11 minutes lamination to complete the process.

In the embodiments shown in FIGS. 9-12, the electric connections 110 form electric connection between each of the photovoltaic cells 100. More specifically, as shown in the figures, each of the electric connections 110 connects with a front side of one photovoltaic cell 100 and a back side of another photovoltaic cell 100; thus, forming electrical connection among different photovoltaic cells 100.

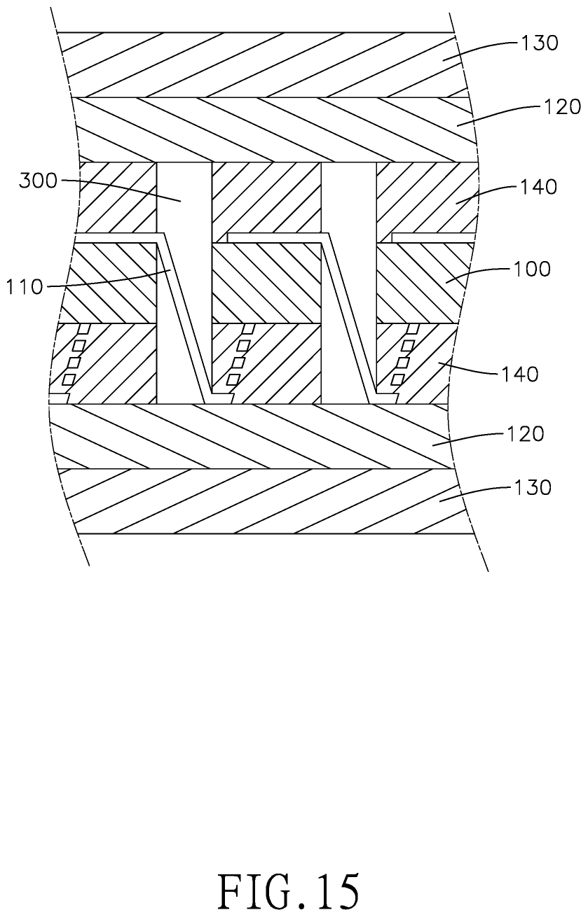

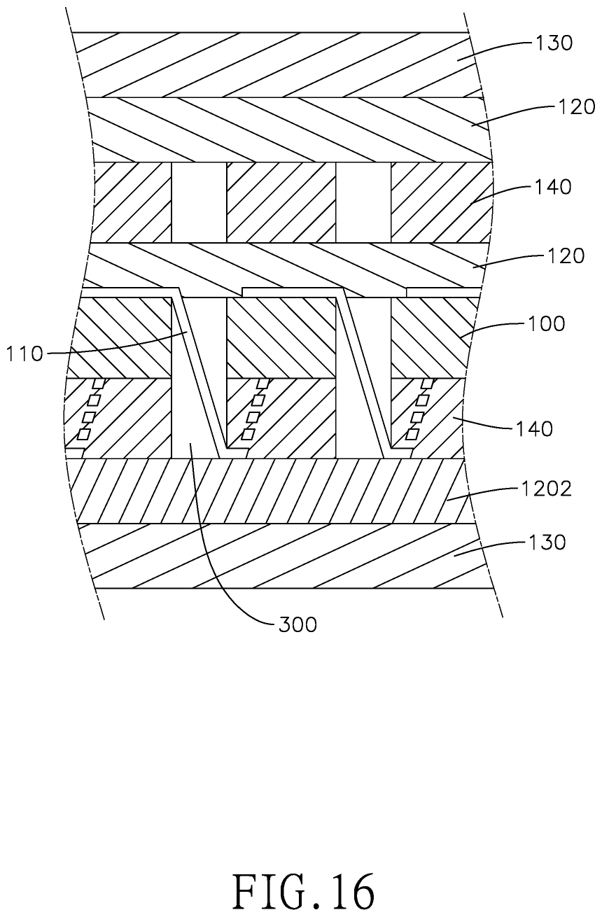

With reference to FIG. 15, in another embodiment of the present invention, a reinforcing layer 140 may be placed on at least a side of the photovoltaic cells 100 to strengthen the photovoltaic device. As an example, the reinforcing layer 140 may include glass fiber layer or polyethylene terephthalate (but is not limited to these two materials). In some embodiments, the reinforcing layer 140 is provided in the form of a plurality of tiles and each tile has approximately the same size as a photovoltaic cell 100. However, in some other embodiments, it does not require the reinforcing layer 140 to be in the form of a plurality of tiles. In other embodiments, the tiles of the reinforcing layer 140 may be added to a side or both sides of each of the photovoltaic cells 100. With reference to FIGS. 15 and 16, the reinforcing layer 140 does not need to be directly on the photovoltaic cells 100. A middle layer (e.g., an adhesive layer 120, as shown in FIG. 16) of other material may be placed between the photovoltaic cells 100 and the reinforcing layer 140. Further as shown in FIGS. 15 and 16, a via may be provided on each of the reinforcing layers 140 for conductors to pass through to form electric connection 110 between each of the photovoltaic cells 100.

It is worth mentioning that the tile size can range from 0.5×0.5 inch²-6×6 inch². A plurality of tiles can be connected with each other to form larger area of photovoltaic unit. The ratio between the width or length of the tile and the spacing between tiles may be from 0.3-3 inches to enhance bendability and rollable property of the photovoltaic device.

In another embodiment, the reinforcing layers 140 may be provided on both sides of the photovoltaic cells. The reinforcing layers may be different materials. As an exemplary embodiment (shown in FIG. 20), one of the reinforcing layers 141 may be PET on a side of the photovoltaic cells and fiber glass on the other side of the photovoltaic cells 100. The materials of the reinforcing layers 140, 141 can be selected according to different applications of the present invention. The reinforcing layers 140, 141 may have the same dimension as the photovoltaic cells 100.

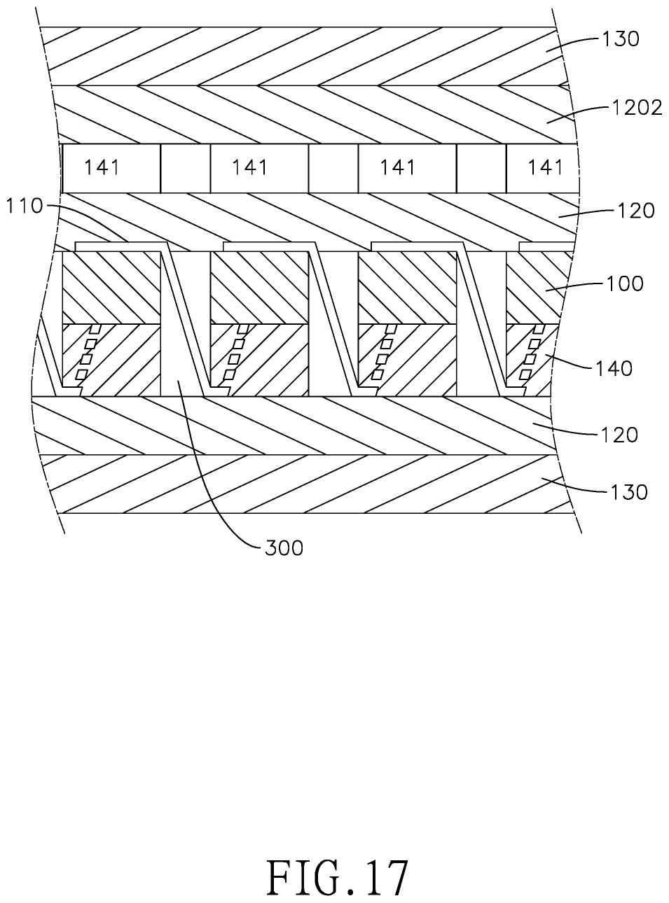

In the embodiments shown in FIG. 17 (which the multiple layer structure consists reinforcing layers 140, 141), a via may be provided on each of the reinforcing layers 140. The conductors pass through the reinforcing layers 140 to form electric connection between each of the photovoltaic cells 100. In some cases, the reinforcing layers 140, 141 may have the same dimension as the photovoltaic cells 100. More specifically, as shown in the figures, the reinforcing layer 140 is on a side of the photovoltaic cells 100, each of the electric connections 110 passes through the via and connects with a front side of one photovoltaic cell 100 and a back side of another photovoltaic cell 100; thus, forming electrical connection among different photovoltaic cells 100.

In one embodiment of the present invention, more than two layers of adhesive layers may be provided. As shown in FIG. 17, the adhesive layers 120 may be the same material or different material. Thus, the method for manufacturing the photovoltaic device may comprise a step of depositing a secondary adhesive layer 1202 on a side of the reinforcing layer 140.

The following are other exemplary embodiments of the present invention. The present invention is not limited to the multiple layer structure below.

In another aspect of the present invention, the photovoltaic device may be 5-layer multiple layer structure. With reference to FIG. 10, the multiple layer structure comprises a plurality of photovoltaic cells 100 electrically coupled to form a photovoltaic matrix. Adhesive layers 120 are respectively applied to a side or both sides of the photovoltaic matrix. The adhesive layers 120 may be selected from thermoset plastic, TPU, EVA, and other materials having similar physical or chemical properties. Furthermore, two encapsulant layers 130 are respectively provided on a side of each of the adhesive layers 120. The encapsulant layers 130 may be selected from (but not limited to) materials such as: cured silicone, fiber glass, polyethylene terephthalates (PET), ethylene-vinyl acetate (EVA), thermoplastic polyurethane (TPU), polyurethane (PU), Teflon, polyvinyl fluoride, and polyvinyl butyral (PVB) . . . etc. In this embodiment, at least one encapsulant layer 130 may be cured silicone.

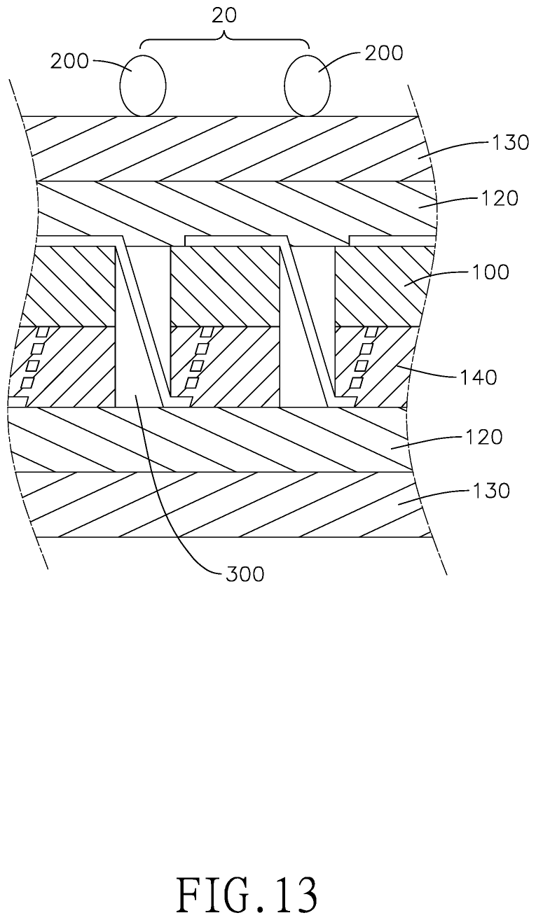

As shown in FIG. 13, in one embodiment of the present invention, the photovoltaic device may be a 6-layer multiple layer structure. In additional to the 5-layer multiple layer structure, an additional reinforcing layer 140 is placed on a side of the photovoltaic cells 100, or between the photovoltaic cells 100 and the adhesive layer 120 to increase mechanical strength of the photovoltaic device. The reinforcing layer 140 may be fiber glass or polyethylene terephthalate; however, the reinforcing layer 140 may be other materials as long as they can provide additional mechanical strength. The reinforcing layer 140 is provided in plurality quantity matching the number of the photovoltaic cells 100. In some embodiments, the reinforcing layer 140 comprises a plurality of tiles. The size of the tiles may be approximately the same as a photovoltaic cell 100. As shown in FIG. 13, after placing the reinforcing layers 140 on a side of the photovoltaic cells 100, the two adhesive layers 120 are respectively deposited onto a side of the reinforcing layer 140 and the photovoltaic cells 100. Alternatively, with reference to FIG. 15, the reinforcing layer 140 may be placed on both sides of the photovoltaic cells 100 to strengthen the photovoltaic device. In this case, the photovoltaic device may be a 7-layer multiple layer structure. The encapsulant layers 130 may be selected from (but not limited to) materials such as: cured silicone, fiber glass, polyethylene terephthalates (PET), ethylene-vinyl acetate (EVA), thermoplastic polyurethane (TPU), polyurethane (PU), Teflon, polyvinyl fluoride, and polyvinyl butyral (PVB), . . . etc. In this embodiment, at least one encapsulant layer 130 may be cured silicone.

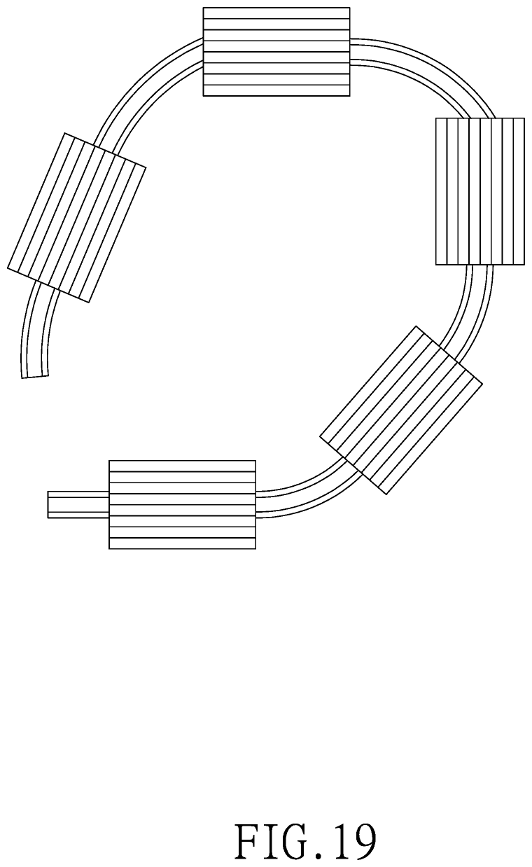

With reference to FIG. 19, in other embodiments, the adhesive layer 120 may be deposited on a side or both sides of the photovoltaic cells 100, such that one of the adhesive layers 120 is situated between the photovoltaic cells 100 and the reinforcing layers 140, and the other adhesive layer 120 is anywhere between the encapsulant layer 130 and the photovoltaic cells 100. An additional secondary adhesive layer 1202 may be provided on a side of the reinforcing layer 140, which is between the reinforcing layers 140 and the encapsulant layer 130. In these embodiments, the multiple layer structure also comprises a total of 7 layers, as shown in FIG. 19. The reinforcing layers 140 are provided in plurality quantity matching the number of the photovoltaic cells 100. The reinforcing layer 140 may be fiber glass or polyethylene terephthalate; however, the reinforcing layer 140 may be other materials as long as they can provide additional mechanical strength. In some embodiments, the reinforcing layer 140 comprises a plurality of tiles. The size of the tiles may be approximately the same as a photovoltaic cell 100; however, this feature may not be required in other embodiments. As shown in FIG. 19, after placing the reinforcing layers 140 on a side of the photovoltaic cells 100, the secondary adhesive layer 1202 is deposited onto at least one side of the reinforcing layer 140. The encapsulant layers 130 may be selected from (but not limited to) materials such as: cured silicone, fiber glass, polyethylene terephthalates (PET), ethylene-vinyl acetate (EVA), thermoplastic polyurethane (TPU), polyurethane (PU), Teflon, polyvinyl fluoride, and polyvinyl butyral (PVB) . . . etc. However, in this embodiment, at least one encapsulant layer 130 may be cured silicone.

As shown in FIG. 17, in one embodiment of the present invention, the multiple layer structure may comprise multiple layers of reinforcing layers and adhesive layers. As an exemplary embodiment, a total of 8 layers is illustrated. Therefore, there are a total of two separate reinforcing layers and three adhesive layers in the present embodiment. The reinforcing layers 140, 141 may be provided on both sides of the photovoltaic cells 100. The reinforcing layers 140, 141 may be directly on a side of the photovoltaic cells 100, or they may be indirectly on a side of the photovoltaic cells 100; for example, the adhesive layer 120 may come between the photovoltaic cells 100 and the reinforcing layer 141. And the secondary adhesive layer 1202 may be between the reinforcing layer 141 and the encapsulant layer 130. The two reinforcing layers 140, 141 may be the same material or different materials. As an example, one of the reinforcing layers may be PET, and the other may be fiber glass. However, the reinforcing layers 140, 141 are not limited to these two materials; the materials of the reinforcing layers 140, 141 can be selected according to different applications of the present invention. The reinforcing layers 140, 141 are provided in plurality quantity matching the number of the photovoltaic cells 100. The reinforcing layers 140, 141 may be fiber glass or polyethylene terephthalate; however, the reinforcing layers 140, 141 may be other materials as long as they can provide additional mechanical strength. In some embodiments, the reinforcing layers 140, 141 comprise a plurality of tiles. The size of the tiles may be approximately the same as a photovoltaic cell 100. However, in some other embodiments, this feature is not required. The encapsulant layers 130 may be selected from (but not limited to) materials such as: cured silicone, fiber glass, polyethylene terephthalates (PET), ethylene-vinyl acetate (EVA), thermoplastic polyurethane (TPU), polyurethane (PU), Teflon, polyvinyl fluoride, and polyvinyl butyral (PVB) . . . etc. In this embodiment, at least one encapsulant layer 130 may be cured silicone.

It is worth mentioning that in the aforementioned embodiments, a via may be provided on each of the reinforcing layers 140 for conductors to pass through to form electric connection 110 between each of the photovoltaic cells 100. In the present invention, the plurality of photovoltaic cells 100 is electrically coupled with each other (may be in parallel or in series) to form a photovoltaic matrix to achieve the desired electric power output.

In some other embodiments, the photovoltaic device in accordance with the present invention may further comprise a back sheet and/or a front sheet. The back sheet and/or the front sheet is intended to protect the photovoltaic device from UV radiations, and moisture penetration from the environment. It further promotes electrical insulation and durability to the photovoltaic device. The back sheet and/or the front sheet may be polymer or a combination of polymers, such as fiber glass, polyamide (PA), polyethylene terephthalate (PET), PC (Polycarbonate), ETFE (Ethylene-tetra-fluoro-ethylene), silicone, polyolefin, TPT (Tedlar-Polyester-Tedlar), and polyvinylidene fluoride (PVDF) . . . etc. The back sheet and/or the front sheet may be applied on top of the encapsulant layer to provide additional rigidity to the photovoltaic device.

In the case which fiber glass is used as back sheet to increase high temperature resistance and dimensionally stability of the photovoltaic device, polytetrafluoroethylene (Teflon™) coated glass fiber may be used as encapsulant layer comprising cured silicone. The use of the combination of polytetrafluoroethylene and fiber glass as back sheet brings the following advantages to the photovoltaic device: stain resistance, lightweight, operating temperature range −50° C. to +260° C., excellent chemical resistance, high electrical insulative and dielectric properties, dimensional stabilities under heat and pressure, low electrical losses, mildew and fungus resistance, and ultra-Violet, infra-Red, Micro-wave, radio frequency resistance. However, cured silicone in accordance with the present invention also has the above advantages as the fiber glass with polytetrafluoroethylene. In addition, cured silicone in accordance with the present invention may be more flexible and tear resistance relative to fiber glass with polytetrafluoroethylene. In some embodiment of the present invention, the combination of cured silicone, polytetrafluoroethylene, and fiber glass can form the encapsulant layer and back sheet of the photovoltaic device. As an example, the encapsulant layer in accordance with the present invention may have a thickness of 100 μm-500 μm, or in another example encapsulant layer in accordance with the present invention may have a thickness 0.5 mm-3 mm. In the present invention, the encapsulant layer has a transmittance of 85-92% for light having wavelength from 300-1000 nm.

For demonstrating the benefits of using cured silicone in accordance with the present invention as the encapsulant layer of the photovoltaic device, photovoltaic devices (photovoltaic cells) are used as the test subject. The following shows the specifications of the photovoltaic cells used in the foregoing tests and experiments:
dimension: 20×20 cm²
weight: 196 g
power output: 10.109(v)×0.5765(A)=5.8278(W)
power output: 0.02973 w/g
spacing between photovoltaic cells: 0.5 cm
Foldability and bendability: 120°-170°

It is worth mentioning that relative to the conventional CIGS photovoltaic cell having the same dimension (20×20 cm², approximately 200 g-300 g). The conventional CIGS photovoltaic cell power has power output per gram of 0.023 w/g-0.035 w/g, which is comparable to the test subject using the cured silicone in accordance with the present invention. Furthermore, the cured silicone encapsulant layer implemented in the present invention has a relatively high light transmittance for visible spectrum wavelengths. The photovoltaic device in accordance with the present invention has a transmittance of 85 to 92% for light having wavelength from 300-1000 nm. Thus, the power conversion efficiency of the present invention can reach 0.02973 w/g. The following provides the experimental results for bonding strength reliability of the photovoltaic device in accordance with the present invention. In the present experiment, the encapsulant layer is cured silicone. The surface energy enhancing material film is PU. In order to test the bonding strength, the cure silicone encapsulant layer with the surface energy enhancing layer, ATSM test method is implemented. The composite is further put under thermal shock under 180° C. for 1 hour and 2 hours respectively, and then tested for the bonding strength again. The results are as follows:

TABLE 1

| Sample | Test method | Bonding Strength |
|---|---|---|
| Original | ASTM | >2 Kgf cm⁻¹ |
| After 20 cycles Thermal | ASTM | >2 Kgf cm⁻¹ |
| shock test | | |

TABLE 2

| Temperature | Time | Bonding Strength |
|---|---|---|
| 180° C. | 1 hr | Same as original |
| 180° C. | 2 hr | Same as original |

The result shows that the bonding force between cured silicone and PU is >2 Kgf cm⁻¹. Evidently, bonding strength does not decrease after being subjected to thermal stress. Furthermore, the bonding strength remain unchanged after cycles of thermal shock. Evidently, the cured silicone encapsulant material in accordance with the present invention can achieve and maintain excellent bonding with conventional adhesive after prolong use.

Another key advantage of using cured silicone as the encapsulant layer material is the excellent electrical insulation property, resistance to moisture and stream, heat and cold resistance, high and low temperature flexibility . . . etc. These properties can help not to generate acetic acid in adhesive layer (particularly EVA) usually caused by thermal or photothermal degradation. So, the electrical connections are not subjected to erosion. The moisture and water permeation rate of the cured silicone in accordance with the present invention is tested under 105° C. and relative humidity of 85%. The results are shown as below:

TABLE 3

| | Water Vapor Transmission Rate for Materials | | |
|---|---|---|---|
| Materials/rate of day | Cycle 1 | Cycle 2 | Cycle 3 |
| Cured silicone | 4.032 × 10⁻⁸(kg/m²s) | 1.195 × 10⁻⁷(kg/m²s) | 4.239 × 10⁻⁸(kg/m²s) |
| back sheet | 4.565 × 10⁻⁸(kg/m²s) | 1.695 × 10⁻⁷(kg/m²s) | 2.663 × 10⁻⁸(kg/m²s) |
| (Tedlar polyester | | | |
| Tedlar/TPT) | | | |

The water resistance ability of the cured silicone in accordance with the present invention is 4×10⁻⁸ to 4.239×10⁻⁸ (kg/m²s) (with thickness being approximately 300 μm). The water vapor transmission rate (WVTR) is calculated by using Fick's diffusion equation:

$$C ( t ) = {C}_{0} + ( {C}_{ex} - {C}_{0} ) \cdot ( 1 - {e}^{\frac{- WVTR}{{C}_{s} d} \cdot t} )$$

According to the table shown above, the WVTR is comparable to back sheet. However, cured silicone encapsulant layer exhibit much better flexibility and tensile strength relative to back sheet, therefore, it is a better encapsulant material. Furthermore, compare to PET, cured silicone help common adhesive such as EVA to not to produce acetic acid, which may erode the electrical connection of the photovoltaic device.

As mentioned earlier, applying cured silicone to a photovoltaic device can promote better reliability and durability of the photovoltaic device after prolong usage. In the following experiment, several samples using different combination of encapsulant materials are tested along with photovoltaic device implementing cured silicone for reliability performance. Each of the samples comprises a top layer, two adhesive layers, a photovoltaic cell, and a bottom layer. The material consisting in the photovoltaic device are:
Sample A: Cured silicone/EVA/Photovoltaic cell/EVA/TPT
Sample B: PET/EVA/Photovoltaic cell/EVA/TPT
Sample C: ETFE/EVA/Photovoltaic cell/EVA/TPT I
Sample D: ETFE/EVA/Photovoltaic cell/EVA/TPT II
Sample E: Cured silicone/EVA/Photovoltaic cell/EVA/Cured Flame retardant silicone+Fiber glass sheet
Sample F: Cured silicone/EVA/Photovoltaic cell/EVA/Cured silicone+Fiber glass sheet

For the initial test, the reliability test is performed on Samples A to D using HAST-S-PLUS (HAST/High-Accelerated Temperature and Humidity Stress Test), PCT (Pressure Cooker test), and ORCA-R2 (EL/electroluminescence). The reliability test condition is as the following:

TABLE 4

| | | Period |
|---|---|---|
| Testing condition | Machine | (hrs/cycle) |
| 105 C./85% RH | HAST | 145 |

The samples are subjected to cycles of humidity and heat exposure to induce deterioration of the photovoltaic cell and the packaging material. The performance of the photovoltaic cells is evaluated under AM 1.5G ONE_SUN to record the change in open circuit voltage (V_{oc}), short circuit current (J_{sc}), fill factor (F.F.), photovoltaic cell efficiency ETA, and power transfer efficiency (n) with respect to time. The test results for the normalized power are shown below.

According to the experiment, the samples still conform to the IEC 60068-2-66 standard after being subjected to 105° C./85% RH for 870 hours. The sample having cured silicone as the top encapsulant layer has better overall performance regarding short circuit current (J_{sc}), fill-factor (F.F.), solar photovoltaic conversion efficiency (η). This is due to the fact that cured silicone has better encapsulation properties performance and help the adhesive layer not to create acetic acid to cause erosion of the interconnection metal. As shown above, the photovoltaic cell having cured silicone as encapsulant layer has the best F.F. and ETA deterioration rate performance.

Furthermore, Sample A has a degradation rate less than 10%, which is better than the result of 25% of the other three (Sample B, C, and D). Evidently, the photovoltaic cell having cured silicone in accordance with the present invention as encapsulant material also has good power transfer efficiency performance relative to other samples. For V_{oc}−t, J_{sc}−t, F.F.−t, E_{ff}−t electrical performance of the samples after being subjected to 105° C.; RH85% testing condition in HAST machine, we find that Sample A, Sample B and Sample D (excluding Sample C) exhibit good V_{oc}−t and J_{sc}−t performance.

Sample A (Cured silicone/EVA/cell/EVA/TPT) has better J_{sc}−t, F.F.−t and E_{ff}−t performance relative to other samples. The test result suggests that the cured silicone material may have better water vapor resistance performance and relative higher glass transition temperature. The efficiency degradation rate for Sample A is less than 10%, which is better than the result of 25% of the other samples.

Based on the experiment and analysis, we refer to cured silicone is a better material encapsulant as the upper layer of the photovoltaic module.

The samples are subjected to the test conditions listed below for the EL imaging.

TABLE 6

| | | Period |
|---|---|---|
| Testing condition | Machine | (hrs/cycle) |
| 85° C./85% RH | HAST | 1000 |
| 105° C./85% RH | HAST | 145 |
| 105° C./100% RH | HAST | 24 |
| 121° C./100% RH | PCT | 24 |

In other embodiments of the present invention, the cured silicone encapsulant layer can be modified to exhibit flame-retardant property. Meanwhile, cured silicone can be combined with other flexible material to form new type cured silicone based composite materials. This not only aims to maintain better reliability performance of cured silicone for photovoltaic module, but also to keep the performance of the back sheet material of the like TPT back sheet. The following experiments are conducted for testing the performance of the photovoltaic cells having modified cured silicone (with flame-retardant property), and the performance of the photovoltaic cells having modified cured silicone in combination with flexible functional layer.

The following samples being tested are:
Sample E: Cured silicone/EVA/Photovoltaic cell/EVA/Cured Flame retardant silicone+Teflon coated glass fiber
Sample F: Cured silicone/EVA/Photovoltaic cell/EVA/Cured silicone+Teflon coated glass fiber.

These samples go through 105° C.; RH85% testing condition under HAST machine, with 120 hours per cycle. These samples go through a total of 500 testing hours.

For the test results of V_{oc}−t, J_{sc}−t, F.F.−t, E_{ff}−t, they show that although V_{oc}−t performance of Sample F decays relatively more than Sample E, the final power conversion efficiency performance after 500 hours decays relatively less than Sample E. This result shows that we can add the different functional properties in back sheet using cured silicone (such as flame retardant) according to different applications and needs. Since silicone is a UV resistant material, exhibit superior stability against extreme humidity and temperature, we assume that it could emerge as one of the choices for the back sheet materials.

It is worth mentioning that the back sheet material with cured silicone-based material encapsulation can help enhancing photovoltaic device's flexibility and maintaining better reliability. Meanwhile, it can also help reducing module thickness.

In addition to the advantages mentioned above, cured silicone has the better properties relative to other polymer materials. Furthermore, cured silicone has a relatively smaller thickness, more flexibility, and also higher water resistance ability. Therefore, it is ideal for the encapsulation of photovoltaic devices. For the adhesive, EVA and thermoplastic polyurethane (TPU) can be used due to their flowing properties after melting. The combination of cured silicone (with surface treatment in accordance with the present invention) and the adhesive layer can seal the photovoltaic device much better than the conventional packaging material, which promote the performance and endurance of the photovoltaic device.

Other physical parameters of the cured silicone with surface treatment in accordance with the present invention are tested and listed below:
Tensile strength (MPa): 0.5-15 (MPa)
Tear strength (kN/m): 1-40 kN/m
Elongation range percent: 150% to 1000%
Compression set range: 5% to 50%
Hardness (shore A) range: 10 A to 90 A
Dielectric constant: specific number or range: 2.5-2.9
Transmittance range: 85% to 92%

In some embodiments of the present invention, the cured silicone in accordance with the present invention may be modified chemically or physically to exhibit different enhanced properties. For examples, the cured silicone may be modified as transparent silicone, thermally conductive silicone, and flame retardant silicone . . . etc. according to different applications of the present invention. For exemplary purpose, the physical parameters of these three materials are tested and listed below:

### Transparent Silicone:

Tensile strength (MPa): 0.5-15 (MPa)
Tear strength (kN/m): 1-40 kN/m
Elongation range percent: 150% to 1000%
Compression set range: 5% to 50%
Hardness (shore A) range: 10 A to 90 A
Thickness: 100-500 μm or 0.5 mm to 5 mm

### Thermally Conductive Silicone:

Thermal conductivity: 0.6 to 1 W/m·k (80% to 85% thermal conductive fillers)
Tensile strength >82 Kgf/cm²
Tear strength >20 Kgf/cm
Elongation 200%-500%
Hardness (shore A) range: 40 A to 90 A
Thickness: 100-500 μm or 0.5 mm to 5 mm

### Flame Retardant Silicone:

Tensile strength >82 Kgf/cm²
Tear strength >20 Kgf/cm
Elongation 360%-500%
Hardness (shore A) range: 40 A to 90 A
Thickness: 100-500 μm or 0.5 mm to 5 mm

In another embodiment of the present invention, a bendable photovoltaic device and the method for manufacturing thereof are disclosed. With reference to FIGS. 4-12, the method for manufacturing the bendable photovoltaic device comprises the following steps:

Step 001: electrically coupling the plurality of photovoltaic cells 100 to form the photovoltaic matrix. The plurality of photovoltaic cells 100 is connected in series or in parallel; however, other types of electrical connection configurations may also be possible depending on the type of application. Each of the photovoltaic cells 100 is placed next to the other with a space arrangement 300 provided there between.

Step 002: depositing an adhesive layer 120 on a side or both sides of the photovoltaic matrix. The adhesive layer 120 may be selected from (but not limited to) ethylene-vinyl acetate (EVA), polyurethane (PU), and thermoplastic polyurethane (TPU). In some embodiments, the adhesive layer 120 is placed directly on both sides of the photovoltaic matrix. As a result, as shown in FIG. 9, a total of two adhesive layers 120 are provided. However, in other embodiments, the adhesive layers 120 may be placed indirectly on both sides of the photovoltaic matrix. More specifically, other layers may come between the photovoltaic matrix and the adhesive layers 120.

Step 003: respectively applying an encapsulant layer 130 on a side of each of the adhesive layers 120. The encapsulant layer 130 is purposely placed on the most outer layer of the bendable photovoltaic device to resist moisture and external force for preventing erosion and damage of the photovoltaic device. The encapsulant layer 130 need to be soft, bendable, having good shock absorbent property, good thermal expansion property, and excellent light permeability. In one embodiment of the present invention, the encapsulant layer 130 may be selected from (but not limited to) non-silicone based materials such as: polyethylene terephthalates (PET), ethylene-vinyl acetate (EVA), thermoplastic polyurethane (TPU), polyurethane (PU), and polyvinyl butyral (PVB) . . . etc. In this embodiment, the encapsulant layer 130 may act as the functional layer/coating mentioned earlier and provide additional function or structural reinforcement; or the encapsulant layer 130 may be adhered with other functional layer/coating for gaining additional function or structural reinforcement. In another embodiment, the encapsulant layer 130 may be silicone-based material such as silicone rubber, cured silicone, or silicone composite materials.

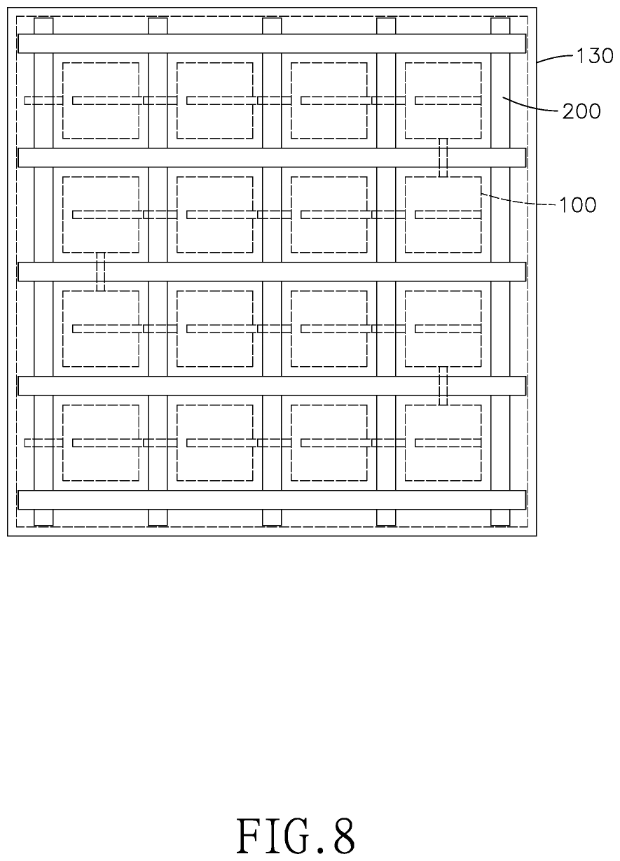

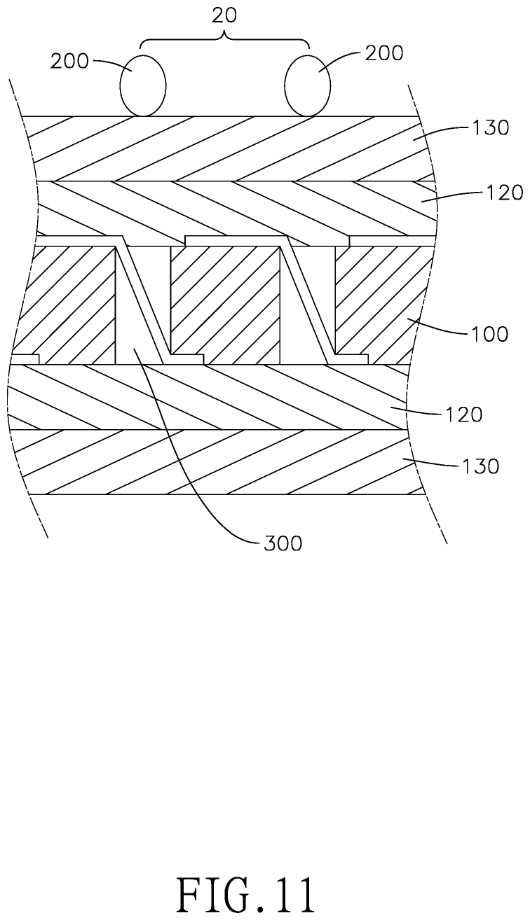

Step 004: placing a molding grid 20 on a side of the encapsulant layer 130. A space arrangement of the molding grid 20 corresponds to the space arrangement 300 of the plurality of photovoltaic cells 100. In the present invention, each of the plurality of photovoltaic cells 100 is placed next to the other with a predetermined space arrangement 300 in between, as shown in FIGS. 8 and 11. The space arrangement 300 may be simply a space between each of the photovoltaic cells 100. The molding gird 20 comprises a plurality of rods 200. During a lamination process, the rods 200 are place on top of the encapsulant layers with positions corresponding to the space arrangement 300 between the photovoltaic cells 100. In one embodiment of the present invention, the rods 200 may be rigid material such as metal or flexible material such as silicone strips.

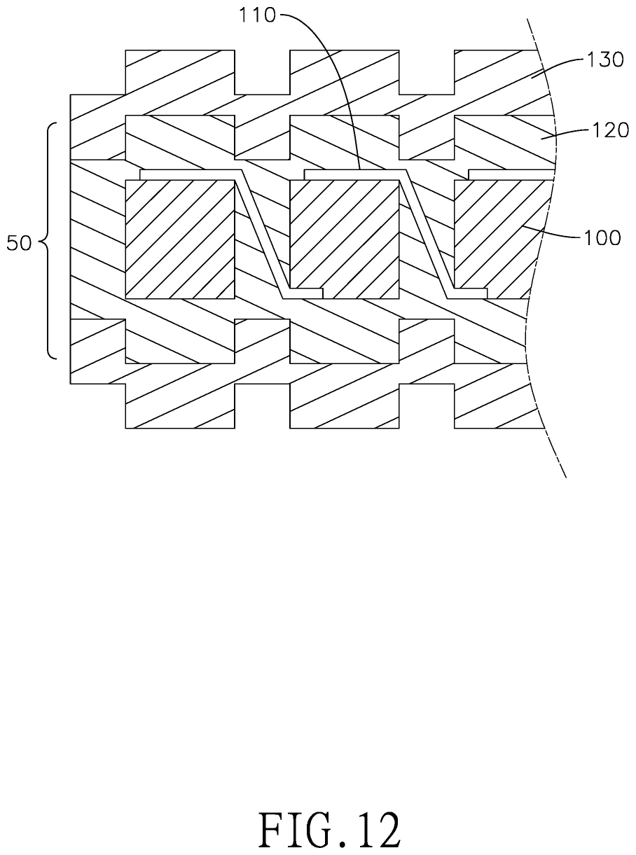

Step 005: exerting a mechanical pressure on the encapsulant layers 130 via the molding grid 20 such that the adhesive layers 120 and the encapsulant layers 130 are compressed to fill the space arrangement 300 between two of the adjacent photovoltaic cells 100 to form the bendable photovoltaic device, as shown in FIG. 12.

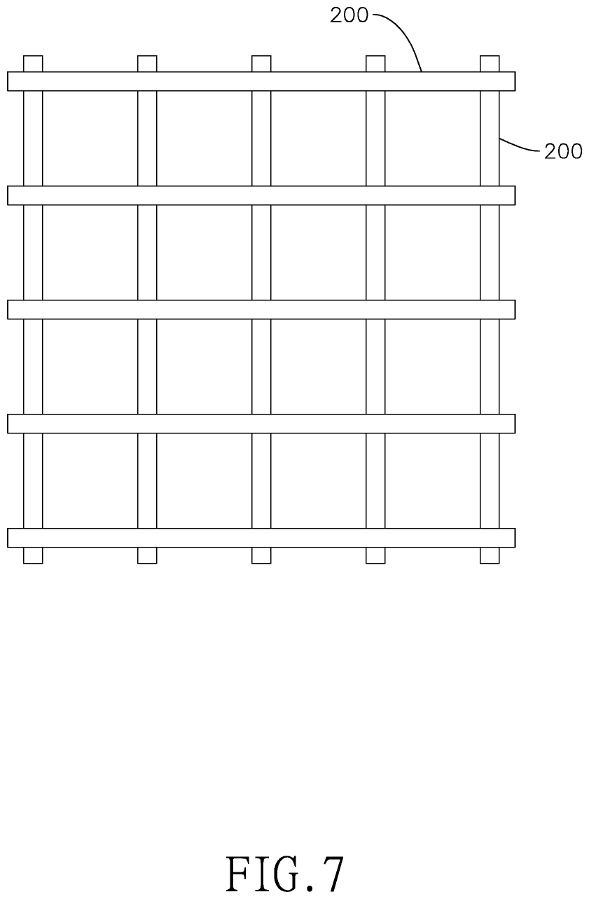

The following further describes details regarding the molding grid 20 and the formation process of the bendable connecting portion. With reference to FIGS. 7, 8, 11, and 12, a molding grid 20 is placed on at least one side of the multiple layer structure. The molding grid comprises a plurality of crisscrossing rods 200. The plurality of crisscrossing rods 200 may be formed with silicone strips and other non-rigid materials. In one embodiment of the present invention, the molding grid 20 is placed in a way that the position of the plurality of crisscrossing rods 200 corresponds to the position of the space arrangement 300 between two of the adjacent photovoltaic cells 100. A mechanical force is applied by the molding grid to at least one side of the multiple layer structure. The adhesive layer 120 and the encapsulant layer 130 are compressed and fill into the space arrangement 300 between two of the adjacent photovoltaic cells 100 due to high pressure and thermal energy to form a bendable connecting portion 50 between the adjacent photovoltaic cells 100. Since there is a step height (thickness) difference between the photovoltaic cells 100 and the bendable connecting portions, it enhances the bendability of the photovoltaic device so that the photovoltaic device can be curved to fit a variety of surfaces having different curvatures. The implementation of the reinforcing layers 140 in some embodiment of the present invention can further increase the step height difference; thus, enhancing the bendability of the present invention. In the present invention, the plurality of photovoltaic cells 100 is electrically coupled with each other (may be in parallel or in series) to form a photovoltaic matrix to achieve the desired electric power output.

As mentioned earlier, the molding grid implemented in the present invention are place in a horizontal position corresponding to the space between the photovoltaic cells and/or the space between each of the reinforcing layers. Thereby, the pressure and thermal energy exerted by the molding grid can focus on the site where the spacing between the photovoltaic cells situate. The liquidity of the material of the encapsulant layer and the adhesive layer are increased such that the encapsulant layer and the adhesive layer are pressed into the spacing to fill the spacing and encompass the electrical connection between each of the photovoltaic cells. In turn, the electrical connection is protected by the bendable connecting portion, and the position of the electrical connection is fix by the bendable connecting portion. In the present invention, the formation of the bendable connecting portion 50 is incorporated with the lamination process of the adhesive layers and the encapsulant layers. No additional process for the formation of the bendable connecting portion 50 is needed. This can greatly reduce the cost and manufacturing process complexity for bendable photovoltaic devices.

Since the rods 200 are placed in positions corresponding to the space arrangement 300, the pressure exerted by the rods 200 of the molding grid 20 can focus on the site where the space arrangement 300 between the photovoltaic cells 100 is situated. In addition to mechanical pressure, thermal energy may also be applied to the encapsulant layers 130 and the adhesive layers 120 to increase fluidity of these two layers. As a result, the material of the adhesive layers 120 and the encapsulant layers 130 can flow into the space arrangement 300 more easily to fill the space arrangement 300.

As shown in FIG. 12, once the space arrangement 300 is completely filled with the adhesive layer 120 and the encapsulant layer 130, these two layers become the bendable connecting portion between each of the photovoltaic cells 100; and thereby, forming the bendable photovoltaic device. In the present embodiment, thermal energy and mechanical pressure is applied to the adhesive layers and the encapsulant layer for better fluidity and adhesion during the manufacturing process. As an example, the manufacturing process is carried under 140° C., 100 kPa, for 20 minutes. The molding grid 20 is removed after the process is completed.

With reference to FIG. 13, in another embodiment of the present invention, a reinforcing layer 140 may be placed on a side of the photovoltaic cells to strengthen the bendable photovoltaic device. The reinforcing layer 140 may include glass fiber layer or polyethylene terephthalate (but not limited to these two materials). The reinforcing layer 140 is provided in the form of a plurality of tiles and each tile has approximately the same size as a photovoltaic cell 100. Therefore, a space arrangement 300 can be maintained between each of the tiles of the reinforcing layer 140 so the encapsulant layer and adhesive layer can be filled into the space arrangement 300 between the reinforcing layer 140 to form a bendable connecting portion 50. With reference to FIG. 15, in other embodiments, the tiles of the reinforcing layer 140 may be added to a side or both sides of each of the photovoltaic cells 100. The reinforcing layers 140 may be the same material or different materials. With reference to FIG. 16, in some embodiments, when the reinforcing layer 140 is on the photovoltaic cells 100, the reinforcing layer 140 does not need to be directly on the photovoltaic cells 100. A middle layer (e.g., an adhesive layer) of other material may be placed between the photovoltaic cells 100 and the reinforcing layer 140 so the reinforcing layer 140 is indirectly on the photovoltaic cells 100.

With reference to FIG. 17, as an exemplary embodiment, one of the reinforcing layers 140,141 may be PET on a side of the photovoltaic cells 100 and fiber glass on the other side of the photovoltaic cells 100. The materials of the reinforcing layers 140, 141 can be selected according to different applications of the present invention. In the embodiments shown in FIGS. 13-17, a via may be provided on each of the reinforcing layers 140 for conductors to pass through to form electric connection 110 between each of the photovoltaic cells 100. In some cases, the reinforcing layers 140, 141 may have the same dimension as the photovoltaic cells 100. Therefore, a space arrangement 300 can be maintained between each of the tiles of the reinforcing layers 140, 141 so the encapsulant layer and adhesive layer can be filled into the space arrangement 300 between the reinforcing layers 140, 141 to form the bendable connecting portion.

The following describes several exemplary embodiments of the packaging structure of the bendable photovoltaic device in accordance with the present invention.

As shown in FIG. 12, a bendable photovoltaic device in accordance with one embodiment of the present invention is illustrated. The bendable photovoltaic device may be a 5-layer multiple layer structure. The multiple layer structure comprises a plurality of photovoltaic cells 100 electrically coupled to form a photovoltaic matrix. Adhesive layers 120 are respectively applied to both sides of the photovoltaic matrix. The adhesive layers 120 may be selected from thermoset plastic, TPU, EVA, and other materials having similar physical or chemical properties. Furthermore, two encapsulant layers 130 are respectively provided on a side of each of the adhesive layers 120. The encapsulant layer 130 may be selected from (but not limited to) non-silicone-based materials such as: polyethylene terephthalates (PET), ethylene-vinyl acetate (EVA), thermoplastic polyurethane (TPU), polyurethane (PU), ethylene tetraflouroethylene (ETFE) and polyvinyl butyral (PVB) . . . etc. In another embodiment, the encapsulant layer is silicone-based material such as silicone rubber, cured silicone, or silicone composite materials. In the present invention, the photovoltaic cells are placed in a matrix configuration; a bendable connecting portion 50 is provided between two adjacent photovoltaic cells. The bendable connecting portion 50 is formed with the adhesive layer 120 and the encapsulant layer 130. During the final lamination stage of the packaging process, a mechanical force and thermal energy are provided to the encapsulant layer 130 and the adhesive layer 120 such that the material forming the encapsulant layer 130 and the adhesive layer 120 are bonded firmly with each other to form the packaging structure of the of the bendable photovoltaic device. Meanwhile, as shown in FIGS. 9 and 10, the encapsulant layer 130 and the adhesive layer 120 are pressed into a space arrangement 300 between the two adjacent photovoltaic cells 100. As a result, a bendable connecting portion 50 is formed therebetween by the encapsulant layer 130 and the adhesive layer 120. In some embodiments of the present invention, the bendable connecting portion 50 encompasses the electric connection 110 between the photovoltaic cells 100. The electric connection 110 is formed by electrically coupling the plurality of photovoltaic cells 100 in the photovoltaic matrix prior to the deposition of the adhesive layer 120 and the encapsulant layer 130. The plurality of photovoltaic cells 100 is connected in series or in parallel according to different types of application. It is apparently that no additional process or material is required for the formation of the bendable connecting portion.

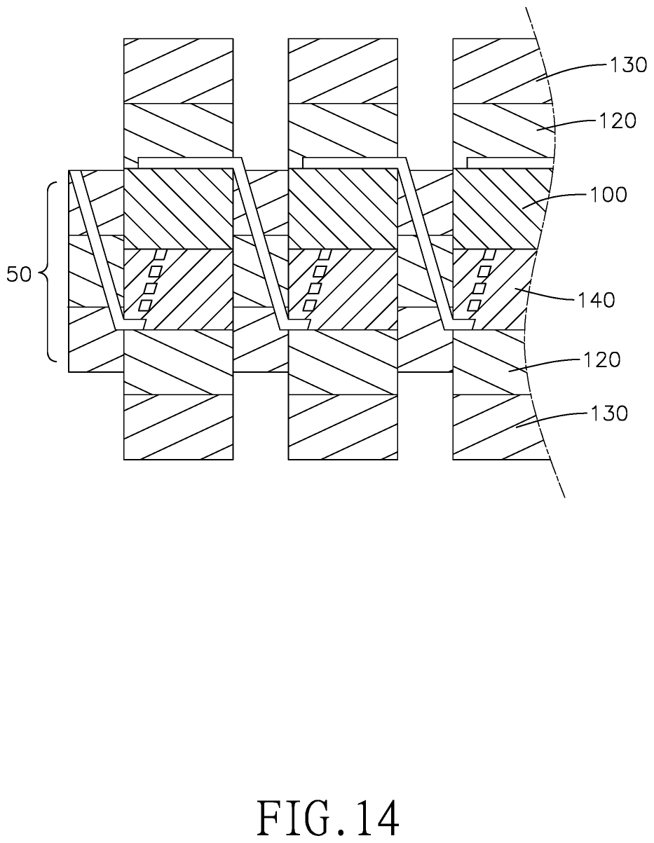

As shown in FIGS. 13-14, in one embodiment of the present invention, the bendable photovoltaic device may comprise 6 layers multiple layer structure. In additional to the 5 layers multiple layer structure, an additional reinforcing layer 140 is placed on a side of the photovoltaic cells 100, or between the photovoltaic cells 100 and the adhesive layer 120 to increase mechanical strength of the photovoltaic device. The reinforcing layer 140 may be fiber glass or polyethylene terephthalate; however, the reinforcing layer 140 may be other materials as long as they can provide additional mechanical strength. The reinforcing layer 140 is provided in plurality quantity matching the number of the photovoltaic cells 100. In some embodiments, the reinforcing layer 140 comprises a plurality of tiles. The size of the tiles may be approximately the same as a photovoltaic cell 100. Therefore, a space arrangement 300 is maintained between each of the reinforcing layers 140, which corresponds the space arrangement 300 between each of the photovoltaic cells 100. As shown in FIGS. 13-14, after placing the reinforcing layers 140 on a side of the photovoltaic cells 100, two adhesive layers 120 are respectively deposited onto a side of the reinforcing layers 140 and the photovoltaic cells 100. During the final lamination stage of the packaging process, a mechanical force and thermal energy are provided to the encapsulant layer 130 and the adhesive layer 120 such that the material forming the encapsulant layer 130 and the adhesive layer 120 are bonded firmly with each other to form the packaging structure of the of the bendable photovoltaic device. Meanwhile, the encapsulant layer 130 and the adhesive layer 120 are pressed into a space arrangement 300 between the two adjacent photovoltaic cells 100 and two adjacent tiles of reinforcing layers 140. As a result, a bendable connecting portion 50 is formed therebetween by the encapsulant layer 130 and the adhesive layer 120. In some embodiments of the present invention, the bendable connecting portion 50 encompasses the electric connection 110 between the photovoltaic cells 100.

With reference to FIG. 15, in another embodiment of the bendable photovoltaic device of the present invention, the reinforcing layers 140 may be implemented on both sides of the photovoltaic cells 100 for enhancing the strength of the photovoltaic device. The adhesive layers 120 and encapsulant layers 130 are respectively provided on a side of each of the two reinforcing layers 140. In this embodiment, the multiple layer structure comprises a total of 7 layers. As mentioned earlier, the size of the tiles of the reinforcing layers 140 may be approximately the same as a photovoltaic cell 100. Therefore, a space arrangement is maintained between each of the reinforcing layers 140, which corresponds the space arrangement 300 between each of the photovoltaic cells. The bendable connecting portion 50 between each of the photovoltaic cells 100 is formed by lamination process which provides thermal energy and pressure to the adhesive layer 120 and the encapsulant layer 130 such that the space arrangement 300 is completely filled with the adhesive layer 120 and the encapsulant layer 130.

With reference to FIGS. 16 and 17, in other embodiments, multiple adhesive layers and reinforcement layers may be implemented. The adhesive layer 120 may be deposited on a side or both sides of the photovoltaic matrix, such that one of the adhesive layers 120 is situated between the photovoltaic cells 100 and the reinforcing layers 140, and the other adhesive layer 120 is between the encapsulant layer 130 and the photovoltaic cells 100. An additional secondary adhesive layer 1202 may be provided on a side of the reinforcing layers 140, which is between the reinforcing layers 140 and the encapsulant layer 130. In these embodiments, the multiple layer structure comprises a total of 8 layers, as shown in FIG. 16. The reinforcing layers 140 are provided in plurality quantity matching the number of the photovoltaic cells 100. The reinforcing layers 140 may be fiber glass or polyethylene terephthalate; however, the reinforcing layers 140 may be other materials as long as they can provide additional mechanical strength. In some embodiments, the reinforcing layers 140 comprise a plurality of tiles. The size of the tiles may be approximately the same as a photovoltaic cell 100. Therefore, a space arrangement is maintained between each of the reinforcing layers 140, which corresponds the space arrangement 300 between each of the photovoltaic cell 100. As shown in FIGS. 16 and 17, after placing the reinforcing layers 140 on a side of the photovoltaic cells 100, the secondary adhesive layer 1202 is deposited onto at least one side of the reinforcing layer 140. The step height difference between the bendable connecting portion 50 and photovoltaic cells 100 facilitates the bending of the bendable photovoltaic device. In other embodiments, the step height difference may be purposely increased to further enhance the bendability of the bendable photovoltaic device. During the final lamination stage of the packaging process, a mechanical force and thermal energy are provided to the encapsulant layer 130 and the adhesive layer 120 such that the material forming the encapsulant layer 130 and the adhesive layer 120 are bonded firmly with each other to form the packaging structure of the of the bendable photovoltaic device. Meanwhile, the encapsulant layer 130 and the adhesive layer 120 are pressed into a space arrangement 300 between the two adjacent photovoltaic cells 100. As a result, a bendable connecting portion 50 is formed therebetween by the encapsulant layer 130 and the adhesive layer 120. In some embodiments of the present invention, the bendable connecting portion 50 encompasses the electric connection 110 between the photovoltaic cells 100.

As shown in FIG. 17, in one embodiment of the present invention, the multiple layer structure may comprise multiple layers of reinforcing layers 140 and 141 and adhesive layers 120 and 1202. As an exemplary embodiment, a total of 8 layers is illustrated. Therefore, there are a total of two separate reinforcing layers 140 and 141 and three adhesive layers in the present embodiment. The reinforcing layers 140 and 141 may be provided on both sides of the photovoltaic cells 100. The reinforcing layers 140 and 141 may be directly on a side of the photovoltaic cells 100, or they may be indirectly on a side of the photovoltaic cells; for example, the adhesive layers 120 may come between the photovoltaic cells 100 and the reinforcing layers 141. The two reinforcing layers 140 and 141 may be the same material or different materials. As an example, one of the reinforcing layers may be PET, and the other may be fiber glass. However, the reinforcing layers 140 and 141 are not limited to these two materials; the materials of the reinforcing layers can be selected according to different applications of the present invention. The reinforcing layers 140 and 141 are provided in plurality quantity matching the number of the photovoltaic cells 100. The reinforcing layers 140 and 141 may be fiber glass or polyethylene terephthalate; however, the reinforcing layer 140 and 141 may be other materials as long as they can provide additional mechanical strength. In some embodiments, the reinforcing layer s 140 and 141 comprise a plurality of tiles. The size of the tiles may be approximately the same as a photovoltaic cell 100. Therefore, a space arrangement 300 is maintained between each of the reinforcing layers, which corresponds the space arrangement 300 between each of the photovoltaic cell 100. The bendable connecting portion 50 between each of the photovoltaic cells 100 is formed by lamination process which provides thermal energy and pressure to the adhesive layer 120 and the encapsulant layer 130 such that the space arrangement 300 is completely filled with the adhesive layer 120 and the encapsulant layer 130.

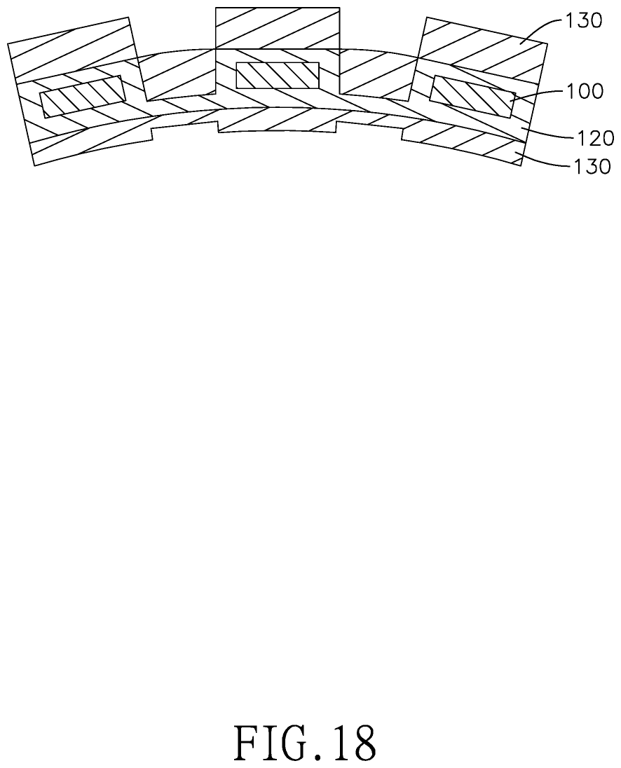

With reference to FIG. 18, in the bendable photovoltaic device in accordance with the present invention, the step height difference between the bendable connecting portion 50 and photovoltaic cells 100 facilitates the bending of the bendable photovoltaic device. When an external force is applied, the curvature of the bendable photovoltaic device can be easily modified to fit surfaces having different curvatures.

The bendable photovoltaic device in accordance with the present invention does not require the photovoltaic cells to be bendable. The photovoltaic cells may be silicone based photovoltaic cells. Other types of photovoltaic cells such as GaAs photovoltaic cells or III-V multi-junction solar cell may be implemented. The encapsulant layer may be plasticized materials or compound plasticized materials. Meanwhile, both the encapsulant layer and the adhesive layer need to have fluidity when subjected to mechanical pressure or thermal energy so that they can fill the space between the photovoltaic cells easily after being pressed and molded by the molding grid. In the present embodiment, EVA is used as adhesive for bonding the photovoltaic cells with the encapsulant layer. The thickness of EVA is, but not limited to about 0.45 mm. Thermal energy and mechanical pressure are applied to EVA for better fluidity and adhesion during the manufacturing process. In some embodiments, the manufacturing process is carried under 140° C., 100 kPa, for 20 minutes. The molding grid is removed after the process is completed.

In some embodiments of the present invention, the bendable photovoltaic device in accordance with the present invention may be configured to be rollable. With reference to FIG. 19, the step height between the bendable connecting portion 50 and the photovoltaic cells 100 may be increased to differentiate the stress received by the bendable connecting portion 50 and the photovoltaic cells 100. Furthermore, the spacing between the photovoltaic cells 100 may also be increased so that the length of the bendable connecting portions 50 are increased accordingly. As a result, the photovoltaic device can be easily bent or rolled due to the stress difference between the bendable connecting portion 50 and the photovoltaic cells 100. As mentioned earlier, the bendable connecting portions 50 are composed of only polymers, thermoplastics, and flexible adhesive. The polymer layer mentioned herein can be PET, ETFE, polyolefin, silicone, and silicon/PU; the thermoplastics mentioned herein can be thermoplastic polyurethane (TPU) . . . etc.; and the flexible adhesive mentioned herein can be EVA, TPU . . . etc. The thickness of the bendable connecting portions 50 is relatively thin when comparing to that of the prior arts. The bendable connecting portions 50 are also more flexible and bendable relative to that of the prior arts. Many of the photovoltaic devices in the prior arts need to rely on flexible solar cells such as CIGS, ITO based solar cell in order to achieve flexibility/bendability; or in some other cases, a large area of solar cells need to be cascaded together to achieve flexibility/bendability. On the other hand, the present invention can achieve flexibility/bendability with simple structures, which is beneficial for manufacturing efficiency and usability.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A photovoltaic device comprising:
a photovoltaic cell;
an adhesive layer, provided on a side of the photovoltaic cell; and
an encapsulant layer, provided on the adhesive layer to encapsulate the photovoltaic cell;
wherein the encapsulant layer comprises cured silicone, the cured silicone is cured prior to being provided on the adhesive layer.

2. The photovoltaic device of claim 1, wherein the cured silicone is adhered to the encapsulant layer via laminating process.

3. The photovoltaic device of claim 1, wherein the encapsulant layer further comprises a mediator and a surface energy enhancing material for increasing a surface energy of the encapsulant layer.

4. The photovoltaic device of claim 3, wherein the mediator comprises silane.

5. The photovoltaic device of claim 4, wherein the mediator comprises trimethoxy(vinyl) silane (CAS: 2768-02-7) and (3-Glycidyloxypropyl) triMethoxysilane (CAS: 2530-83-8)

6. The photovoltaic device of claim 3, wherein the mediator is self-crosslinking silane.

7. The photovoltaic device of claim 1, wherein the cured silicone is high consistency rubber (HCR) silicone, fluorosilicone rubber, and room temperature vulcanize silicone.

8. The photovoltaic device of claim 1, wherein the encapsulant layer has a surface energy of approximately 36-38 mN/m.

9. The photovoltaic device of claim 3, wherein the mediator has a thickness of 1-5 μm.

10. The photovoltaic device of claim 3, wherein the surface energy enhancing material is polyurethane.

11. The photovoltaic device of claim 1, wherein the encapsulant layer has a thickness of 100 μm-500 μm.

12. The photovoltaic device of claim 1, wherein the encapsulant layer has a thickness of 0.5 mm-3 mm.

13. The photovoltaic device of claim 1, wherein the adhesive layer has a thickness of approximate 0.05 mm to 0.5 mm.

14. The photovoltaic device of claim 1, wherein the adhesive layer comprises ethylene vinyl acetate, or thermoplastic polyurethane.

15. The photovoltaic device of claim 1, wherein the encapsulant layer has a transmittance of 85%-92% for light having wavelength from 300-1000 nm.

16. The photovoltaic device of claim 1, wherein the encapsulant layer is cured with platinum-based catalyst.

17. The photovoltaic device of claim 1, wherein the adhesive layer is provided on both sides of the photovoltaic cell.

18. The photovoltaic device of claim 1, wherein the encapsulant layer comprising cured silicone is provided on both sides of the photovoltaic device.

19. A method of packaging a photovoltaic cell, comprising:
applying an adhesive layer on a side of a photovoltaic cell; and
applying an encapsulant layer on the adhesive layer,
wherein the encapsulant layer comprises cured silicone, the cured silicone is cured prior to being provided on the adhesive layer,
wherein the encapsulant layer is laminated to the adhesive layer to form a packaging of the photovoltaic cell.

20. The method of packaging a photovoltaic cell of claim 19, further comprising a step of applying a mediator and a surface energy enhancing material on the encapsulant layer for increasing a surface energy of the encapsulant layer prior to applying the encapsulant layer on the adhesive layer.

21. The method of packaging a photovoltaic cell of claim 10, wherein the mediator comprises silane.

22. The photovoltaic device of claim 21 wherein the mediator comprises trimethoxy(vinyl) silane (CAS: 2768-02-7) and (3-Glycidyloxypropyl) triMethoxysilane (CAS: 2530-83-8).

23. The method of packaging a photovoltaic cell of claim 20, wherein the surface energy enhancing material is polyurethane.

24. The method of packaging a photovoltaic cell of claim 19, further comprising the step of: laminating the adhesive layer and the encapsulant layer under 90 kPa to 110 kPa of pressure, with process temperature of 100° C. to 150° C. for 15-20 minutes.

25. The method of packaging a photovoltaic cell of claim 19, further comprising the step of: laminating the adhesive layer and the encapsulant layer under approximately 100 kPa of pressure, with process temperature of approximately 140° C., going through 4 minutes pumping and baking the module for removing the air between the encapsulants and the adhesive, and moving forward to 11 minutes lamination to complete the process.

26. The method of packaging a photovoltaic cell of claim 20, wherein the mediator and the surface energy enhancing material are cured under approximately 90° C.-150° C. for 3-10 minutes to complete bonding of the mediator and the surface energy enhancing material prior to being applied to the silicone.

27. The method of packaging a photovoltaic cell of claim 20, wherein the mediator and the surface energy enhancing material are cured under approximately 130° C. for 3-10 minutes to complete bonding of the mediator and the surface energy enhancing material prior to being applied to the silicone.

28. The method of packaging a photovoltaic cell of claim 20, wherein the silicone, the mediator and the surface energy enhancing material are cured under approximately 110° C. for 3-5 minutes to complete the cross linking and interlocking reaction of the mediator and the silicone to create the cured silicone.

29. The method of packaging a photovoltaic cell of claim 21, wherein the mediator has a thickness of 1-2 μm.

30. The method of packaging a photovoltaic cell of claim 19, wherein the adhesive layer has a thickness of 0.05 mm to 0.5 mm.

31. The method of packaging a photovoltaic cell of claim 19, wherein the adhesive is selected from a group consisting thermoset polymer plastic, thermoplastic polyurethane, ethylene-vinyl acetate, polyvinylbutyral, and hot-melt adhesive.

32. The method of packaging a photovoltaic cell of claim 20, wherein the surface energy enhancing material is provided on both sides of the encapsulant layer.

33. The photovoltaic device of claim 19, wherein the cured silicone is cured with platinum-based catalyst.

34. The photovoltaic device of claim 19, wherein the cured silicone is high consistency rubber (HCR) silicone, fluorosilicone rubber and room temperature vulcanize silicone.

35. The photovoltaic device of claim 20, wherein the mediator is self-crosslinking silane, acrylic acid, methyl acrylate, or acrylic acid ethyl ester.

36. The photovoltaic device of claim 19, wherein the adhesive layer is provided on both sides of the photovoltaic cell.

37. The photovoltaic device of claim 19, wherein the encapsulant layer comprising cured silicone is provided on both sides of the photovoltaic cell.

38. A surface treatment method for cured silicone, comprising:
applying a mediator to a surface energy enhancing material and curing the mediator for forming chemical bond between the mediator and the surface energy enhancing material, wherein the mediator comprises silane; and
applying a silicone on the mediator and curing the mediator and the cured silicone, the mediator crosslinking with the surface energy enhancing material to form chemical bond between the mediator and the surface energy enhancing material.

39. The method of claim 38, wherein the surface energy enhancing material comprising polyurethane (PU) having a functional group comprising isocyanate group, or hydroxyl group.

40. The method of claim 38, wherein the mediator comprises trimethoxy(vinyl) silane (CAS: 2768-02-7) and (3-Glycidyloxypropyl) triMethoxysilane (CAS: 2530-83-8).

41. The method of claim 40, wherein the surface energy enhancing material is cured under approximately 90° C. to 150° C. for 3 to 10 minutes to complete crosslinking and interlocking reaction of the mediator and the surface energy enhancing material.

42. The method of claim 40, wherein a bonding force between the surface energy enhancing material and the cured silicone is from 55 N/5 cm to 65 N/5 cm.

43. The method of claim 42, wherein the surface energy enhancing material is cured under approximately 130° C. for 3-10 minutes to complete crosslinking and interlocking reaction of the mediator and the surface energy enhancing material.

44. The method of claim 43, wherein a bonding force between the surface energy enhancing material and the cured silicone is from 90 N/5 cm to 110 N/5 cm.

45. The method of claim 38, wherein the cured silicone has a surface energy of 36-38 mN/m.

46. The method of claim 38, wherein the surface energy enhancing material and the mediator are provided on both sides of the encapsulant layer.

47. A multiple layer structure for photovoltaic device comprising a cured silicone layer, comprising:
a substrate layer, adhered to a side of the multiple layer structure via an adhesive layer; and
a functional layer provided on a side of the cured silicone layer,
wherein the cured silicone layer is treated with a surface treatment method comprising:
applying a mediator to a surface energy enhancing material and curing the mediator for forming chemical bond between the mediator and the surface energy enhancing material, wherein the mediator comprises silane; and
applying a silicone on the mediator and curing the mediator and the silicone, the mediator crosslinking with the surface energy enhancing material to form chemical bond between the mediator and the surface energy enhancing material.

48. The multiple layer structure of claim 47, wherein the functional layer is substantially transparent.

49. The multiple layer structure of claim 48, wherein the functional layer is an anti-reflection coating or water vapor protection layer.

50. The multiple layer structure of claim 47, wherein the substrate layer comprises textile material.

51. The multiple layer structure of claim 47, wherein the substrate layer is a metal layer.

52. The multiple layer structure of claim 47, wherein the substrate layer is a glass layer or a glass fiber layer.

53. The multiple layer structure of claim 47, wherein the substrate layer is a flexible layer selected from ETFE, PET, ABS, and PC.

54. The multiple layer structure of claim 47, wherein the adhesive is selected from a group consisting thermoset polymer, thermoplastic polyurethane, ethylene-vinyl acetate, polyvinylbutyral, and hot-melt adhesive.

55. The multiple layer structure of claim 47, comprising another cured silicone layer provided on the side which the multiple layer structure is adhered to the substrate layer, wherein the cured silicone layer is adhered to the substrate layer via lamination.

56. The multiple layer structure of claim 47, wherein the cured silicone is a flame retardant silicone having tensile strength >82 Kgf/cm², tear strength >20 Kgf/cm, elongation of 360%-500%, and hardness of 40 A to 90 A.

57. The multiple layer structure of claim 47, wherein the cured silicone is a thermally conductive silicone having thermal conductivity of 0.6 to 1 W/m·k, tensile strength >82 Kgf/cm², tear strength >20 Kgf/cm, elongation of 200%-500%, and hardness of 40 A to 90 A.

58. The multiple layer structure of claim 47, wherein the cured silicone is a transparent silicone having tensile strength of 0.5-15 (MPa), tear strength of 1-40 KN/m, elongation range percent of 150% to 1000%, compression set range of 5 to 50 and hardness of 10 A to 90 A.

59. A method of manufacturing a bendable photovoltaic device, the method comprising:
electrically coupling a plurality of photovoltaic cells to form a photovoltaic matrix;
depositing an adhesive layer on a side of the photovoltaic matrix;
applying an encapsulant layer on a side of the adhesive layer;
placing a molding grid on a side of the encapsulant layer, wherein a space arrangement of the molding grid corresponds to a space arrangement of the plurality of photovoltaic cells; and
exerting a mechanical pressure on the encapsulant layer via the molding grid such that the adhesive layer and the encapsulant layer are compressed to fill a space arrangement between two of the adjacent photovoltaic cells to form the bendable photovoltaic device.

60. The method of claim 59, wherein the encapsulant layer is cured silicone.

61. The method of claim 59, wherein the adhesive layer is ethylene vinyl acetate, thermoplastic polyurethanes, polyethylene terephthalates, and polyurethane.

62. The method of claim 59, wherein the molding grid comprises a plurality of silicone strips.

63. The method of claim 59, further comprising the step of respectively providing a reinforcing layer on at least one side of each of the plurality of photovoltaic cells.

64. The method of claim 63, wherein the reinforcing layer is fiber glass or polyethylene terephthalate.

65. The method of claim 63, wherein the reinforcing layer is provided between the photovoltaic cells and the adhesive layer.

66. The method of claim 63, further comprising a step of depositing a secondary adhesive layer on a side of the reinforcing layer.

67. The method of claim 65, wherein the reinforcing layer is provided between the adhesive layer and the secondary adhesive layer.

68. The method of claim 59, wherein the mechanical pressure is approximately 100 kPa under 140° C. for 20 minutes.

69. The method of claim 63, wherein the reinforcing layer is provided in the form of a plurality of tiles and each tile has approximately a same size as each of the photovoltaic cells.

70. The method of claim 69, wherein a space arrangement is maintained between each of the tiles of the reinforcing layer such that the space arrangement between the tiles of the reinforcing layer corresponds to the space arrangement between two of the adjacent photovoltaic cells.

71. The photovoltaic device of claim 59, wherein the adhesive layer is provided on both sides of the plurality of photovoltaic cells.

72. The photovoltaic device of claim 59, wherein the encapsulant layer comprising cured silicone is provided on both sides of the bendable photovoltaic device.

73. A bendable photovoltaic device comprising:
a plurality of photovoltaic cells electrically coupled to form a photovoltaic matrix;
an adhesive layer, provided on a side of the photovoltaic matrix; and
an encapsulant layer, provided on the adhesive layer;
wherein a bendable connecting portion is formed between two adjacent photovoltaic cells and comprises the adhesive layer and the encapsulant layer.

74. The bendable photovoltaic device of claim 73, wherein the encapsulant layers is cured silicone.

75. The bendable photovoltaic device of claim 73, further comprising a reinforcing layer on at least one side of each of the plurality of photovoltaic cells.

76. The bendable photovoltaic device of claim 75, wherein the reinforcing layer is fiber glass or polyethylene terephthalate.

77. The bendable photovoltaic device of claim 75, wherein the reinforcing layer is provided between the photovoltaic cells and the adhesive layer.

78. The bendable photovoltaic device of claim 75, further comprising a secondary adhesive layer provided between the reinforcing layer and the encapsulant layer.

79. The bendable photovoltaic device of claim 75, wherein the reinforcing layer is provided between the adhesive layer and the secondary adhesive layer.

80. The bendable photovoltaic device of claim 73, wherein the adhesive layer is ethylene vinyl acetate or thermoplastic polyurethanes.

81. The bendable photovoltaic device of claim 73, wherein the encapsulant layer is approximately 100 μm to 500 μm

82. The bendable photovoltaic device of claim 73, wherein the reinforcing layer comprises a plurality of tiles and each tile has approximately the same size as a photovoltaic cell.

83. The photovoltaic device of claim 73, wherein the adhesive layer is provided on both sides of the plurality of photovoltaic cells.

84. The photovoltaic device of claim 73, wherein the encapsulant layer comprising cured silicone is provided on both sides of the bendable photovoltaic device.

85. A bendable photovoltaic device comprising:
a plurality of photovoltaic cells electrically coupled to form a photovoltaic matrix;
an adhesive layer, provided on a side of the photovoltaic matrix; and
an encapsulant layer, provided on the adhesive layer;
wherein a bendable connecting portion between two adjacent photovoltaic cells is formed by exerting a mechanical pressure on a side of the encapsulant layer and the adhesive layer via a molding grid.

86. The bendable photovoltaic device of claim 85, wherein the encapsulant layer comprises cured silicone.

87. The bendable photovoltaic device of claim 85, further comprising a reinforcing layer on at least one side of each of the plurality of photovoltaic cells.

88. The bendable photovoltaic device of claim 87, wherein the reinforcing layer is fiber glass or polyethylene terephthalate.

89. The bendable photovoltaic device of claim 87, wherein the reinforcing layer is provided between the photovoltaic cells and the adhesive layer.

90. The bendable photovoltaic device of claim 87, further comprising a secondary adhesive layer provided between the reinforcing layer and the encapsulant layer.

91. The bendable photovoltaic device of claim 87, wherein the reinforcing layer is provided between the adhesive layer and the secondary adhesive layer.

92. The bendable photovoltaic device of claim 85, wherein the adhesive layer is ethylene vinyl acetate or thermoplastic polyurethanes.

93. The bendable photovoltaic device of claim 85, wherein the encapsulant layer is 100 μm to 500 μm.

94. The bendable photovoltaic device of claim 85, wherein the reinforcing layer comprises a plurality of tiles and each tile has approximately the same size as a photovoltaic cell.

95. The photovoltaic device of claim 85, wherein the adhesive layer is provided on both sides of the plurality of photovoltaic cells.

96. The photovoltaic device of claim 85, wherein the encapsulant layer comprising cured silicone is provided on both sides of the bendable photovoltaic device.
